(19) United States
(12) Patent Application Publication
(10) Pub. No.: US 2025/0207017 A1
(43) Pub. Date: Jun. 26, 2025

(54) PHOTOACTIVE ORGANIC LIGANDS AND METHODS FOR RADIATION PATTERNING OF NANOPARTICLES FOR FORMATION OF HIGH QUANTUM YIELD DOWNCONVERTER MATERIALS

(71) Applicant: NanoPattern Technologies, Inc., Chicago, IL (US)

(72) Inventors: Forrest S. Etheridge, Naperville, IL (US); Danielle Russell Chamberlin, Belmont, CA (US); Mehr Un Nisa Zaheer, Chicago, IL (US); Alexis V. Miranda, Des Plaines, IL (US); Marissa M. Tranquilli, Chicago, IL (US); Yu Kambe, Berkeley, CA (US)

(21) Appl. No.: 18/946,872

(22) Filed: Nov. 13, 2024

Related U.S. Application Data
(63) Continuation of application No. 18/129,992, filed on Apr. 3, 2023.
(60) Provisional application No. 63/327,152, filed on Apr. 4, 2022.

(51) Int. Cl. C09K 11/02; B82Y 20/00; B82Y 40/00; C09K 11/08; C09K 11/88; G03F 7/004

(52) U.S. Cl. CPC C09K 11/025; C09K 11/0883; C09K 11/883; G03F 7/0042; B82Y 20/00; B82Y 40/00

(57) ABSTRACT

Photoactive organic ligands used to surface modify nanoparticles are described. The photo active organic ligands can be tailored to absorb radiation within a selected range of wavelengths. Upon absorption of radiation, the ligands react to alter the solubility of the ligand, and may be cleaved, and surface modification of the nanoparticles changes such that solubility of the nanoparticles changes. Coatings prepared with the surface modified nanoparticles can be radiation patterned and developed in accordance to methods described herein. Appropriate selection of a solvent as developer provides image formation facilitated by the difference in solubilities of the nanoparticles. Methods of radiation patterning the coatings are described. Luminescent nanoparticles surface modified with the photoactive organic ligands can be used to form down shifting light emission substrates suitable for use in electronic displays.

### CROSS REFERENCE TO RELATED APPLICATIONS

This application is a continuation of U.S. patent application Ser. No. 18/129,992 filed Apr. 3, 2023 to Etheridge et al., entitled “Photoactive Organic Ligands And Methods For Radiation Patterning Of Nanoparticles For Formation Of High Quantum Yield Downconverter Materials”, which claims priority to co-pending U.S. provisional patent application 63/327,152 filed Apr. 4, 2022 to Etheridge et al., entitled “Photoactive Organic Ligands and Methods for Radiation Patterning of Nanoparticles for Formation of High Quantum Yield Downconverter Materials,” incorporated herein by reference.

### STATEMENT OF FEDERALLY SPONSORED RESEARCH OR DEVELOPMENT

This invention was made with government support under Contract No. 2052728 awarded by the National Science Foundation. The government has certain rights in the invention.

### FIELD OF THE INVENTION

Nanoparticles, such as quantum dots, are surface-modified with photoactive organic ligands that can be tailored to absorb radiation within a selected range of wavelengths. Upon absorption of radiation, the photoactive organic ligands are cleaved such that surface modification of the nanoparticles changes to provide for development of the image into a physical pattern. Coatings of the surface-modified nanoparticles can be radiation patterned to form substrates with luminescent nanoparticles that can be used for down shifting light emissions in electronic displays.

### BACKGROUND OF THE INVENTION

Functional nanoparticles can be used to provide various properties to a material based on the functional properties of the nanoparticles. In particular, nanoparticles can be favorably used for their optical or light emitting properties; for instance, small nanoparticles can be employed for tunable light absorbing or emitting properties. Quantum dots are small particles that have absorption and emission properties based on their size and composition, and can be formed from a range of materials, such as semiconductors. The size dependent emission spectrum within the quantum dots is generally explained as resulting from quantum confinement of the excited state. Semiconductor nanoparticles are generally known as luminescent downconverting particles. These luminescent nanoparticles can be used in display devices to provide emissions in the desired regions of the spectrum.

### SUMMARY OF THE INVENTION

In a first aspect, the invention pertains to a collection of nanoparticles, such as quantum dots, having photoactive organic ligands, in some embodiments with an absorption peak in the ultraviolet spectrum. In some embodiments, the photoactive organic ligands comprise a covalent bond coupled to the absorption state that dissociates following absorption. The photoactive organic ligands comprise a linking group, an activation group and a photoreactive group, wherein the photoreactive group is covalently bonded to the linking group and the activation group, and the linking group binds the photoactive organic ligand to a surface of the nanoparticles.

In another aspect, the invention pertains to a luminescent layer on a substrate comprising nanoparticles, such as quantum dots, having an average thickness of no more than about 25 microns, an optical density of at least about 0.7 and a quantum yield of at least about 35 percent when excited with blue light relative to solution quantum yields.

In another aspect, the invention pertains to a light responsive structural element comprising a dense inorganic particle layer with an average thickness, excluding regions where the dense inorganic particle layer is absent, of at least about 5 average nanoparticle diameters and no more than about 15 microns comprising at least about 60 wt. % nanoparticles and no more than about 10 wt. % organic compositions. The nanoparticles can comprise no more than about 60 wt. % of a first nanoparticle type and at least about 40 wt. % of a second nanoparticle type having an energy bandgap larger than the first nanoparticle type by at least 0.2 eV. The light responsive structural element can have a high excitation absorption, such as in the blue region, and a bandgap alignment suitable for energy transfer between the first and second nanoparticle types. The luminescent layer can have a packing fraction of at least about 60%.

In another aspect, the invention pertains to a light responsive structural element comprising a dense inorganic particle layer with an average thickness of at least about 5 average nanoparticle diameters and no more than about 25 microns comprising at least about 60 wt. % nanoparticles, no more than about 10 wt. % organic compositions and at least about 5 wt. % scattering particles with an average diameter of no more than a 500 nm.

In another aspect, the invention pertains to a light responsive structural element comprising a dense inorganic particle layer with an average thickness of at least about 5 average nanoparticle diameters and no more than about 15 microns comprising at least about 60 wt. % nanoparticles, having an optical density for light at 450 nm of at least about 0.7 OD and a PLQY of at least about 30%.

In another aspect, the invention pertains to a method for radiation patterning a layer disposed on a substrate. The method comprises: providing a layer comprising a collection of surface modified nanoparticles, wherein the surface modified nanoparticles comprise nanoparticles and photoactive organic ligands, each photoactive organic ligand comprising a linking group, a photoreactive group covalently bonded to the linking group, and the linking group binds the photoactive organic ligand to a surface of the nanoparticles, and the photoreactive group absorbs light to alter the solubility properties of the photoactive organic ligand; irradiating the layer with radiation in an imagewise manner to form a first latent image comprising irradiated and non-irradiated portions of the layer, wherein irradiation results in the reaction of the photoreactive group in the irradiated portion; and selectively removing portions of the irradiated or non-irradiated portions of the layer while the other portion remains substantially intact, to form a developed layer.

In other aspects, the invention pertains to a method for patterning a layer of nanoparticles, in which the nanoparticles comprise ligands having UV absorption and a photocleavable covalent bond, the method comprising: irradiating the layer with patterned UV light to form a latent image, and contacting the irradiated layer with a developer to pattern the layer according to the latent image.

In additional aspects, the invention pertains to a patterned coating on a substrate, the patterned coating comprising islands of luminescent nanoparticles at a volume packing density of at least about 60% and having a quantum yield of at least 80% relative to solution quantum yields with an optical density of at least 0.7 with an emission spectrum from 500 nm to 750 nm.

### BRIEF DESCRIPTION OF DRAWINGS

FIG. 1 is a schematic perspective view showing propagation of light through selected components, including a quantum dot layer, of an exemplary display device.

FIG. 2 is a schematic top view showing an exemplary arrangement of sub-pixels in a RGB display device.

FIG. 3 is a schematic conceptual representation showing a change in functional groups of an exemplary photoactive organic ligand as a result of the ligand undergoing a photochemical reaction.

FIG. 4A is a schematic representation showing exemplary photochemical reactions of the photoactive organic ligands described herein.

FIG. 4B is a schematic conceptual representation showing an exemplary change in surface functionality of nanoparticles that is imparted by photochemical reaction of the photoactive organic ligands as described in FIG. 3.

FIG. 5A is a schematic illustration of exemplary luminescent particles in a closest packed configuration with a smaller particle in an interstitial site.

FIG. 5B is a schematic illustration showing a small portion of small exemplary luminescent particles organizing around a large scattering particle, in which the small particle packing continues both around the larger scattering particle and outward until encountering additional scattering particles.

FIG. 6 is a schematic illustration showing radiation patterning and development of a layer of quantum dots surface modified with the photoactive organic ligands described herein.

FIGS. 7A-7G are schematic illustrations which together convey an exemplary method for radiation patterning a layer of surface modified quantum dots exhibiting emission in the red region of the visible spectrum.

FIGS. 8A-8H are schematic illustrations showing radiation patterning a layer of surface modified quantum dots exhibiting emission in the green region of the visible spectrum, which is applied to a patterned substrate previously patterned as described in FIGS. 7A-7G.

FIG. 9 is a plot showing the absorption spectrum of the disulfide of photoactive organic ligand IIIb.

FIG. 10A is an image of a sample formed after patterning and developing a coating including InP/ZnSe/ZnS red quantum dots surface modified with ligand IIIb, InP/ZnS blue quantum dots surface modified with ligand IIIb, and BaTiO₃.

FIG. 10B is an image of the sample shown in FIG. 10A after the sample was subjected to an additional sequence of patterning and developing.

FIG. 11A is a plot of percent photoluminescence quantum yield (calculated according to Eqn. 4) as a function of the weight percent fraction of BaTiO₃ for ink formulations prepared as described in Example 10.

FIG. 11B is a plot of the thickness in microns needed to reach an optical density of one as a function of the weight percent fraction of BaTiO₃ for ink formulations prepared as described in Example 10.

FIG. 12 is a plot of the optical density as a function of the thickness in microns measured for dense semiconducting nanoparticles, and for reported optical densities of semiconducting nanoparticles in a resin, as described in Example 11.

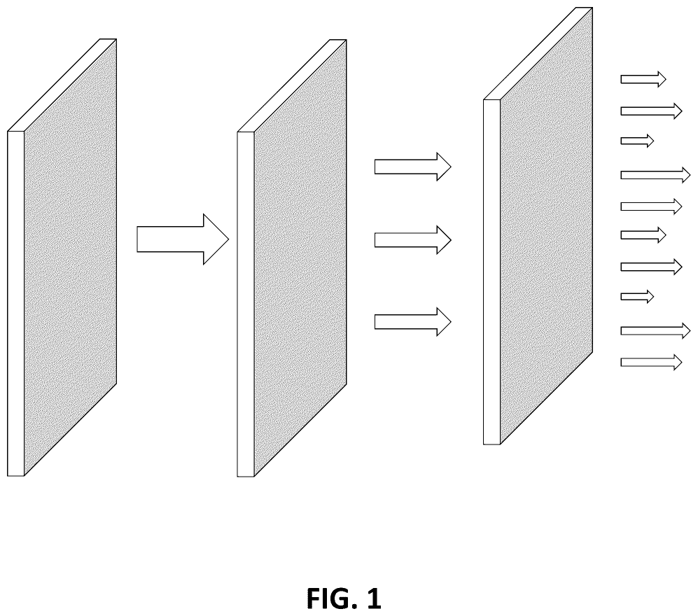

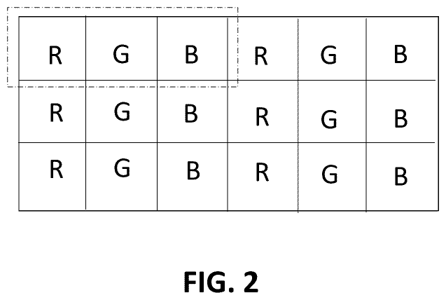

### DETAILED DESCRIPTION OF THE INVENTION

Radiation patterning of nanoparticle coatings is disclosed herein, based on photoactive organic ligands coordinated to nanoparticles, and desirable ligands are taught in this context. In some embodiments, the nanoparticles comprise semiconductor nanoparticles, which in some embodiments can be quantum confined nanoparticles. The nanoparticles can be used as light emitters in display devices based on their frequency downconverting properties. In some embodiments, the nanoparticles having the photoactive organic ligands attached thereto are surface-modified nanoparticles, and the radiation patterning comprises a photolithography process in which coatings of the surface-modified nanoparticles are irradiated and patterned by developing the irradiated coating. In this way, light emitting nanoparticles, such as quantum dots, can be directly patterned into structures for display devices or other functional structures. A latent image formed by patterning with radiation can be developed using different solvents as developers, such that the resulting patterned substrate comprises a negative resist pattern or a positive resist pattern. In contrast to conventional methods, the surface-modified nanoparticles are the photoactive species such that only the surface-modified nanoparticles provide the contrast after irradiation used for patterning. The use of scattering particles can be used to increase effectiveness of the patterning process and to increase the optical density relative to the layer thickness such that the radiation dose can be more effective for patterning. In some embodiments, the processing of patterning steps can be organized to provide for assembly of multiple quantum dot colors to provide for display applications. Other luminescent quantum confined nanoparticles of interest include perovskite nanoparticles with compositions selected to provide desired luminescent color. The processing approaches described herein provide for densely packed quantum dots that can correspondingly achieve high optical density for a thickness of the deposit. The quantum efficiency of red and green quantum dots can be enhanced by mixing with blue quantum dots as well as with scattering particles. Based on the process and material considerations, the quantum dot systems herein are well suited for display applications.

The photoactive organic ligands coordinated to nanoparticles as described herein can be used to prepare radiation patternable coatings having a high density of nanoparticles. For embodiments in which the nanoparticles are quantum confined emitting nanoparticles, radiation patternable coatings having high density or high packing density can be prepared and patterned to obtain color conversion films that can provide high color contrast. Higher packing densities can be obtained compared to densities obtainable with conventional patterning approaches, for example, when nanoparticles are trapped in a polymeric crosslinked matrix. In some embodiments, the organic component of the nanoparticle layer can be no more than about 10 weight percent and in other embodiments no more than about 2 weight percent. Use of mixtures of particle collections with different particle sizes can assist with obtaining a high packing density in a high density nanoparticle film since a polymer matrix would not inhibit effective particle spacing. The high packing densities obtainable with the surface-modified nanoparticles described herein can provide patterned coatings with desired high contrast, suitable for use in high quality electronic, photonic and optoelectronic displays and display devices. The packing density of the surface-modified nanoparticles can exceed, for example, 50% by absolute volume including any pores that may be present in the coating. With respect to quantum confined luminescent nanoparticles, through the blending of smaller blue nanoparticles with red and/or green nanoparticles, the blue nanoparticles can improve the quantum efficiency of the red/green nanoparticles due to reduced non-radiative recombination by spacing them from each other and improve the absorption of the pump light by the red and/or green nanoparticles through energy transfer. The relative particle sizes allow for higher packing densities based on the different particle sizes. Thus, the combination of luminescent nanoparticles can improve external quantum efficiency by reducing non-radiative decay and increasing favorable energy transfer.

Conventional approaches to radiation patterning of nanoparticle coatings can include contacting the coatings with a photoresist having photoactive or other organic compounds such that the nanoparticles in the coating are incorporated into the patterning material. Upon exposure, nanoparticles in exposed areas of the coating become trapped in a crosslinked matrix formed by reaction between components in the coating. The trapped nanoparticles remain after development, and nanoparticles in unexposed areas are washed away or otherwise removed. Nanoparticles employed in radiation patterning are often functionalized or coated with inorganic or organic components to improve their blending with the photoresist compositions, but which can undesirably decrease the packing density of the nanoparticles. Nanoparticle coatings that have been radiation patterned can be used in electronic display devices.

For the performance of the direct patterning approach, upon absorption of radiation of an appropriate wavelength, the photoactive organic ligand bound to the nanoparticles, such as quantum dots, undergoes a dissociation such that some portion of the ligand remains coordinated with the nanoparticle, while a leaving group fragments. During development, the cleaved ligand fragments are removed by developer along with either the irradiated nanoparticles (positive tone development) or unirradiated nanoparticles (negative tone development), depending on development conditions, during post processing of the latent image. Thus, the solubility of the surface-modified nanoparticle changes, and sufficient solubility contrast between the exposed and unexposed portions of the surface provides for an effective physical pattern formation. The difference in solubility between the surface-modified nanoparticle and the photochemically altered nanoparticle provides and/or improves contrast between exposed and unexposed areas of the coating that have been patterned with UV radiation.

Various developments are described herein relating to processing and use of nanoparticles. For example, the ligand based patterning systems can be useful for a range of nanoparticles with selected compositions and suitable for appropriate applications. In general, average particle sizes for nanoparticles for direct ligand based patterning can have average particle sizes of no more than 500 nm, in some embodiments no more than 350 nm, in other embodiments no more than 250 nm, and further embodiments from about 1 nm to about 100 nm. Nanoparticles are available from various commercial sources, such as Nanosys, Invitrogen, American Elements® and Sigma-Aldrich Co. Ltd., and uniformity will depend on the source and synthesis technique. For applications as phosphor, or more generally luminescent particles, such as for blue light down-conversion, quantum confined luminescent, nanoparticles, such as quantum dots, can be particularly desirable to achieve desirable luminescent properties and desirable processing. Quantum dots can be considered to have an average smallest particle dimension from about 1 nm to about 20 nm with an average largest particle dimension of no more than 500 nm, and a full width half maximum for the diameter distribution with commercially available quantum dots of less than 2 nm and in some embodiments less than 0.5 nm. Quantum dots can be considered nanocrystalline, generally comprising semiconductor materials with a core shell structure. Other quantum confined luminescent nanoparticles, such as perovoskites, can have dimensions in the specified nanoparticles ranges above. and may have alternative shapes or structures, such as lacking a shell component. Quantum dots can have roughly spherical shapes, but other shapes can be used. A person of ordinary skill in the art will recognize that additional ranges of average particle sizes within the explicit ranges above are contemplated and are within the present disclosure. The processing described herein is not confined to a particular particle morphology or particular specific size ranges within the broader sizes described above.

The applicant has joined several distinct concepts to provide for improved film formation in conjunction with their integrated patterning function achieved with their functional ligand structure. A significant dimension of providing the improved functionality involves achieving a higher packing density, which is generally targeted at a value of at least about 55%, which refers to the particle occupied volume percent. In comparison, the theoretical limit for closest packing of uniformly sized spherical particles is about 74%, and typical packing for particles with appropriate polymer binders generally would be below 40% (Osinski and Palomaki, Society for Information Display Digest, Volume 50, issue 1, pages 34-37, June 2019, DOI: 10.1002/sdtp.12849. A person of ordinary skill in the art will recognize that additional ranges of packing density within the explicit ranges above are contemplated and are within the present disclosure. One aspect of obtaining the high packing density involves placement of a relatively high ligand coverage over the particle, in which the ligands provide a non-repulsive surface for the particles, such that free energy does not favor a lower density as a result of reduction of particle-particle interactions.

To achieve a desired high packing density, a blend of different particle sizes can contribute significantly to obtaining a good packing. The different particle sizes provide for a denser packing than a monotonic selection of nanoparticles with a relatively narrow particle size distribution. A blend of nanoparticles can involve a plurality of collections of nanoparticles that are generally different with respect to average particle size by at least 1.5 nm, in some embodiments at least about 1.75 nm, and in further embodiments from about 2.0 nm to about 5 nm. A person of ordinary skill in the art will recognize that additional ranges of particle size differences within the explicit ranges above are contemplated and are within the present disclosure.

In addition to the size differences, there can be selected number fraction ratio between nanoparticles in a blend of different sized particles. It may or may not be desirable to have a one to one number ratio. It can also be desirable to have more than two collections of particles to give added flexibility to achieve desired targets of quantum yield and optical density, as well as color. From that perspective, the particles may or may not have different compositions and absorption properties, which depend on absorber size and composition. In either case, the blend of nanoparticles can be similarly patterned using radiation sensitive ligands.

In some embodiments, the particles can have the same composition of the absorber and approximately the same or similar absorption. As described further below, the particle collections can differ according to a shell thickness. If the light absorption and emission is dominated by the core, then the shell thickness can be used to help with packing without significantly impacting the luminescent properties, and the number ratio of the two particle collections can be selected to improve the packing density. If desired, more than two particle collections can be used with different shell thicknesses.

In some embodiments, it is desirable to use a blend of particles with different absorption spectra to provide for energy transfer between particles. In particular, Förster resonance energy transfer (FRET) can be used to transfer energy from a blue or green luminescent nanoparticle to a red luminescent nanoparticle to amplify the red emission, or from a blue luminescent nanoparticle to a green luminescent nanoparticle to amplify the green emission. In this way, the external quantum efficiency of red emission or green emission can be improved. In addition to FRET, other energy transfer mechanisms from shorter wavelength to longer wavelength luminescent nanoparticles are also possible, for example radiative transfer of energy. The principle of FRET to improve external quantum efficiency is described in van der Haar et al., “Eu³⁺ Sensitization Via Nonradiative Interparticle Energy Transfer Using Inorganic Nanoparticles,” J. Phys. Chem Letters 2020, 11:689-695, and Zhang et al., “Enhanced Quantum Efficiency in Mixed Donor-Acceptor Nanocrystal Quantum Dot Monolayers,” ICTON 2011, June 2011, We.D2.4 (http://dx.doi.org/10.1109/ICTON.2011.5971137), both of which are incorporated herein by reference. See also, published U.S. patent application 2020/0063031A to Krames et al., entitled “Converter System,” incorporated herein by reference. The van der Haar article does not consider quantum dots or other quantum confined luminescent nanoparticles, and the Zhang article only considers a monolayer, which limits any non-radiative quenching. The '031 application only exemplifies dry mixed powers with a high ratio of activator phosphors, such as “nanophosphors.”

Since the emission wavelengths of quantum confined luminescent nanoparticles, e.g., quantum dots, and similar nanoparticles may depend on the particle size, the different color quantum confined luminescent nanoparticles may be different sizes. Thus, quantum dots/nanoparticles can be selected to have a selected absorption property, a shell to alter packing and to influence energy transfers, and compositions to provide desired absorption and material properties. Additional particle collections can be selected with these same parameters under consideration, but with appropriate attention to interactions with respect to other particle collections in terms of packing and energy transfer. Specific examples are provided below.

For appropriate embodiments, to improve the optical performance for down conversion of blue light in a display pixel, the material with the luminescent particles, e.g., phosphors, quantum confined nanoparticles/quantum dots, can be mixed with scattering particles to effectively increase the optical path length through the material. To induce significant Mic scattering within the parameters of the coating, scattering particles can have average particle sizes from about 100 nanometers (nm) to about 1 micron. The scattering particles generally are made from an inorganic composition having an index of refraction different from the nanoparticle. The luminescent nanoparticles can have different values of index of refraction depending on the composition, and the scattering particles can have lower or higher indices of refraction relative to the luminescent nanoparticles. Due to the relatively high index of refraction of the dense nanoparticle layer, the scattering particles can have lower indices of refraction relative to the luminescent nanoparticles. In some embodiments, suitable scattering particles can comprise, for example, barium titanate (BaTiO₃), titanium oxide (TiO₂), zirconium oxide (ZrO₂), mixtures thereof, and the like, with relatively high index of refraction but lower indices of refraction as compared to the luminescent nanoparticle film. In other embodiments, suitable scattering particles can comprise significantly lower absolute refractive indices, for example silica (SiO₂). In embodiments in which the scattering particles are significantly larger than the luminescent nanoparticles, the number percent of scattering particles can be significantly less than the weight average values. With lower number average amounts of particles, the patterning can generally be effectively performed without surface modifying the scattering particles with radiation sensitive ligands. In some embodiments, the scattering particles are also surface modified with radiation sensitive ligands, as described further below.

A significant advantage of the direct patterning of the photoluminescent layer relates to the general objective of obtaining a suitably thick layer so that the material absorbs the blue light. Better patterning allows for forming smaller pixel sizes. In some embodiments, multiple patterning steps can be performed to achieve the desired patterning effect. During each step, using a reasonable irradiation fluence, each patterning step may not penetrate sufficiently to penetrate through the entire layer. If, during an irradiation step, the full thickness of the layer is not sufficiently irradiated, a series of irradiation and development steps can be performed to remove sections of material through the layer a portion at a time. Generally, patterning during deposition, such as through ink jet printing, is unable to achieve pixel sizes as small as those created through lithography.

As a downconverter in a display device, a luminescent layer comprising quantum confined semiconductor nanoparticles at a selected location can absorb blue light and emit green or red light. The layer can be formed to absorb essentially all of the blue light, or in some embodiments roughly 85 to 99+% absorbance. The layer thickness can be selected to achieve this degree of absorbance. With a high loading level and available quantum efficiencies, the thickness of the layer is generally on the order of 4 microns or more, and in some embodiments up to 10 microns or more, although the quantitative value is dependent on the material. For ultraviolet (UV) light sources that can appropriately be used for patterning, it generally would not be expected that sufficient UV intensity would penetrate through the entire layer based on the particle loading and thicknesses generally desired. Thus, the ability to do multiple patterning over the same pattern can be beneficial to complete development of the pattern through the full layer, for example two patterning steps may be used.

The formation of ligands for covering the nanoparticles/quantum dots are described in detail below. The surface modified nanoparticles can be dispersed in a suitable liquid, which are described below. The dispersed nanoparticles can be formed into a film on a substrate, such as using spin coating, slot-die coating, uniform spray deposition, or other suitable coating approach. The wet coating is dried to form a dry coating, such as by drying in ambient conditions, drying in an oven, drying using blown hot air, drying using an infrared heater, or a combination thereof, or the like. The dry film can have an average thickness generally no more than about 50 microns, in further embodiments no more than about 35 microns, in other embodiments from about 500 nm to about 40 microns and in other embodiments from about 1 micron to about 25 microns. Thicknesses can be measured with commercial contact or non-contact devices, such as optical devices, contact profilometers or other suitable devices, or estimated from surface loading and packing estimates. A person of ordinary skill in the art will recognize that additional ranges within the explicit ranges above are contemplated and are within the present disclosure.

The deposited films can be patterned using the patterning techniques described herein. For optical applications, relevant optical properties can be evaluated. A significant application is the use for down-conversion of blue LED light to green or red for display applications. In this context, the red or green pixels should not transmit too much of the original blue light in order to obtain desired color output. The absorption of the original input light can be described in terms of the optical density (OD), which is log₁₀(T₀/T), where T₀/T is the inverse of the fraction of the light that is transmitted. Thus, an OD of 1 corresponds with 10% of the incident light transmitted, and OD of 2 is 1% of the incident light transmitted, and similarly for other values. The OD is dependent on the packing density, the absorption of the nanoparticles and the thickness of the film. Generally, it is desirable to have an OD from 0.7 to 2.0 with a film average thickness from about 2 microns to about 20 microns, and in some embodiments it is desirable to have an OD of about 2 or more with a film average thickness of no more than about 15 microns.

For use as a luminescent nanoparticle, the absorbing nanoparticles then emit light following absorption of the incident light. It is generally desirable to have a high quantum yield of light conversion, which conceptually refers to a high probability of an emitted photon for an absorbed photon. After absorbing the light, the particle can undergo non-radiative decay mechanisms that circumvent the luminescence, e.g., fluorescence. The quantum yields can be dependent on the compositions and structure of the layers. Using the processing and layer formation described herein, including optionally a blending of scattering nanoparticles and/or blue absorbing particles to provide energy transfer from strong blue absorbing QDs to red or green emitting QDs, the quantum efficiencies can be within 80% of the dilute solution quantum yield. The quantum yield can be expressed formally for evaluation as the external quantum efficiency, which can also be referred to as the maximum external quantum efficiency or the uncorrected photoluminescence quantum yield. The external quantum efficiency can be evaluated in a context of accounting for device design parameters, but as used herein these factors are not taken into consideration, hence the equivalent reference to a maximum external quantum efficiency, as described further below.

With respect to patterning based on photoreactive ligands, such as photocleavable ligands as described herein, contrast may be further improved by adding organic additives to the developer. A suitable organic additive coordinates with the photochemically altered ligand which results in an increase in solubility in the developer. For example, the additive may comprise a small molecule organic compound such as long chain carboxylic acid, wherein the carboxyl group coordinates to an exposed end of the photochemically altered ligand and the hydrocarbon chain presents itself to developer. Organic additives may be employed in a coating solution used to form a layer of the surface-modified nanoparticles.

The photoactive organic ligand is generally coordinated to a surface of the nanoparticles such that the surface characteristics of the nanoparticles are modified. The photoactive ligands may replace and/or supplement ligands on nanoparticles that may be present from the nanoparticle synthesis and retained to inhibit particle agglomeration. The photoactive organic ligand is coordinated to a surface of the nanoparticles in the sense that it is associated with, attached or bound to, the nanoparticles with sufficient stability such that the surface-modified nanoparticles are suitable for their intended use. The photoactive organic ligand can be coordinated to the surface of the nanoparticles by being physically bound, for example, by absorption or adsorption, or by being chemically bound, for example, by covalent bonds or non-covalent bonds such as ionic bonds or hydrogen bonds.

The materials and patterning processes described herein are suitable for the production of display components that can operate in a color conversion panel for use in conjunction with a suitable backlighting. In some embodiments, blue light is supplied to the color conversion panel according to a selective array, and the color conversion panel outputs the selected light color, although an alternative design could use a white light source. The patterning process described herein allows for efficient photolithography processing as an alternative to inkjet printing. The photolithography patterning for the color conversion panel can fit into process flow using photolithography for the production of other display components. Small pixel sizes for the color conversion panel can be effectively formed. While display applications may be of particular interest, the processing approaches are suitable for a range of other applications such as sensors, optics, or semiconductor device fabrication.

### Nanoparticles

The nanoparticles to which the photoactive organic ligand can be bound can be composed of electrically conductive materials, semiconducting materials, dielectric materials, magnetic materials, catalytic materials, and/or light up-converting materials. Suitable nanoparticles include semiconductors, which can comprise one or more elements of appropriate groups, such as Group 2-Group 16 (e.g., SrS, CuzSe or PbTe), Group 12-Group 16 (e.g., ZnSe), Group 13-Group 15 (e.g., GaAs, which can be referred to as III-V semiconductors based on older terminology), Group 14-Group 16 (e.g., SnTe), and Group 14 (e.g., Si or Ge) semiconductors of the Periodic Table (using the modern group numbering system of 1-18). Suitable nanoparticles to which the ligands can be bound include, for example, metal nanoparticles, metal alloy nanoparticles, metal chalcogenide nanoparticles, metalloid nanoparticles, metal oxide nanoparticles and metalloid oxide nanoparticles. Examples of elements or complexes include metal phosphides, metal sulfides, metal selenides and metal tellurides.

Exemplary nanoparticle compositions include, but are not limited to, AlN, AlP, AlAs, AlSb, Al₂CO, BN, BP, Bas, BaS, BaSe, BaTe, BES, BeSe, BeTe, C (including diamond), CaS, CaSe, CaTe, CdS, CdSe, CdTe, CdPo, Cu, CuF, CuCl, CuBr, CuI, Cu₂S, CuzSe, CuInSe₂, Cu₂ZnSnS₄, Cu₂ZnSnSc₄, GaN, GaP, GaAs, GaSc, GaSb, Ga₂S₃, Ga₂Sc₃, Ga₂Te₃, Ga₂Ge, GeS, GeSe, GeTe, Ge₃N₄, HgS, HgSc, HgTe, HgPo, InN, InP, InAs, InGaP, InSb, In₂S₃, In₂Sc₃, In₂ Te₃, MgS, MgSe, MgTe, PbO, PbS, PbSe, PbTe, Si, SiC, SiGe, Si₃N₄, Al₂O₃, Sn, SnS, SnSe, SnTe, SrS, SrSe, SrTe, ZnO, ZnS, ZnSe, ZnTe, ZnPo and appropriate combinations of two or more. Other exemplary nanoparticle compositions include, for example, HgₓCd₁₋ₓTe, HgₓCd₁₋ₓS, HgₓCd₁₋ₓSe, CdₓZn₁₋ₓTe, CdₓZn₁₋ₓSe, CdₓZn₁₋ₓS, and CuIn₍₁₋ₓ₎GaₓS₂ or CuIn₍₁₋ₓ₎GaₓSe₂ where 0<x<1. Examples of some metal nanoparticles, metal oxide nanoparticle compositions, and metal chalcogenide nanoparticle compositions, to which the ligands can be bound include, for example, Al₂O₃, Au, Ag, Bi, Bi₂S₃, Bi₂Se₃, Bi₂Te₃, CeO₂, Co, CoPt, CoPt₃, Fe, FeO, Fe₂O₃, Fe₃O₄, FePt, HfO₂, InGaZnO, Ni, Pd, Pt, Ru, Rh, SiO₂, ZnO and ZrO₂ and mixtures of two or more.

The nanoparticles to which the photoactive organic ligands can be bound have an average particle diameter in the range of from about 1 nm to about 500 nm, from about 1 nm to about 100 nm, from about 1 nm to about 50 nm, from about 1 nm to about 15 nm, from about 1.5 nm to about 10 nm, or from about 2 nm to about 10 nm, where the average particle diameter is an average along the particles three principal axes. In some embodiments, the nanoparticles can have a particle diameter, as measured along any axis of the structure, of from about 1 nm to about 100 nm, from about 1 nm to about 50 nm, from about 1 nm to about 10 nm, or from about 2 nm to about 10 nm. In this context, diameter can refer to the diameter of substantially spherical particles or also to the distance along the smallest axis of the structure through the particle center, in which the boundaries can be based on drop off of the electron density as measured by an appropriate technique. Suitable techniques for measuring the average particle diameter include, for example, scanning tunneling microscopy and transmission electron microscopy. The nanoparticles can have a variety of regular and irregular shapes, which may reflect a crystal lattice, and include substantially round nanoparticles and other shaped nanoparticles, such as nanorods or nanoplates. Particles of interest include, for example, quantum confined luminescent nanoparticles with average particle diameter of no more than about 20 nm, such as quantum dots, but perovskite nanoparticles can effectively be larger. A person of ordinary skill in the art will recognize that additional ranges of average nanoparticle or particle diameters within the explicit ranges above are contemplated and are within the present disclosure.

In some embodiments, the nanoparticles are quantum dots, which can be referred to in the art with respect to certain roughly spherical quantum confined luminescent nanoparticles, comprising semiconductor nanocrystals having an average diameter of from about 1 nm to about 12 nm, from about 2 nm to about 10 nm, or from about 2 nm to about 8 nm. A roughly spherical shape can refer to particles with no diameter through the center of the particle more than about 50% greater than the average diameter. Particles of interest also include other quantum confined luminescent nanoparticles, which may have non-spherical shapes, such as nanorods. In some embodiments, the semiconductor composition and diameter of the quantum confined luminescent nanoparticles can be selected depending on the desired emission spectrum or wavelength peak.

Generally, the luminescence refers to a down-conversion of frequency, so absorbed light at a first frequency is emitted at a lower frequency with a certain efficiency. For example, CdSe quantum dots having an average diameter of from about 2 nanometers (nm) to about 3 nm tend to emit light in the blue or green regions of the visible spectrum, and CdSe quantum dots having an average diameter of from about 7 nm to about 10 nm tend to emit light in the red region of the visible spectrum. Similarly, indium phosphide (InP) based quantum dots can have an average particle size of 3.1 nm for blue, 5 nm for green and 7.3 nm for red (Nanosys website). A person of ordinary skill in the art will recognize that additional ranges of particle diameter within the explicit ranges above are contemplated and are within the present disclosure.

In general, the semiconductor composition and size of quantum confined nanoparticles, e.g., quantum dots, can be selected to emit energy ranging from near ultraviolet (UV) wavelengths to far infrared (IR) wavelengths. In some embodiments, the semiconductor composition and size of the nanocrystals can be selected such that a narrow emission spectrum is exhibited in the visible range. In some embodiments, the semiconductor composition and the size of the nanocrystals can be selected such that the quantum dots emit light having a sufficiently narrow bandwidth such that the light may be considered monochromatic, or quasi-monochromatic. For example, the quantum dots or other quantum confined luminescent nanoparticles may emit essentially monochromatic red, green or blue light. Quantum confined nanoparticles can have a core-shell structure with one or more shells. The light emission is generally primarily controlled by the core size and composition. Quantum confined nanoparticles are generally produced with some form of organic ligands to reduce or eliminate agglomeration. Patterned coatings comprising surface-modified semiconductor quantum dots emitting monochromatic light can be used in high quality electronic, photonic and optoelectronic displays and display devices. Nanoparticles are commercially available from NNCrystal US Corp. (NN-Labs®), Sigma-Aldrich Co. Ltd., Mesolight LLC (Suzhou Xingshuo Nanotach Co., Ltd.), Nanoco Technologies Ltd., Ocean NanoTech LLC, MK Nano, and Nanosys, Inc.

In some embodiments, the nanoparticles may comprise a perovskite nanoparticles. The perovskite nanoparticles can have the general formula ABX₃ comprising a monovalent halide X bonded to cations of the crystal structure, and the cations can be metallic, organic or inorganic. Perovskite nanoparticles having the general formula ABX₃ include, for example, compositions wherein: A is the monovalent cation of cesium, methylammonium, ethylammonium, formamidinium or a combination thereof; B is a cation of Bi, Cd, Mn, Pb, Sn or Zn or a combination thereof; and X is chloride, bromide or iodide. Specific perovskite nanoparticle compositions include, for example, MAPbX₃, FAPbX₃, MA/EAPbBr₃, FA/CsPbBr₃, MA/CsPbX₃, CsPbX₃, CsPbBr₃, CsSnX₃, Cs₂SnI₆, CsSn/PbX₃, CsPb/MnX₃, CsPb/CdX₃, CsPb/SnX₃, CsPb/ZnX₃, CsPb/BiX₃, and Au—CsPbX₃ wherein: MA is methylammonium; EA is ethylammonium; FA is formamidinium; Au—Cs is cesium auride; and X is chloride, bromide or iodide.

The nanoparticles to which the photoactive organic ligands can be bound may comprise a core/shell nanoparticle having a core and a shell at least partially surrounding the core. Core/shell nanoparticles can have two distinct layers, a semiconductor or metallic core and a shell surrounding the core of an insulating or semiconductor material. The core can comprise a first semiconductor material, and the shell often can comprise a second semiconductor material that is different than the first semiconductor material. Core/shell nanoparticles may be prepared by known synthetic methods as described, for example in U.S. Patent Publication No. US 2022/0085254 A1 to Kurtin et al., entitled “Method For Forming a Composite Having Semiconductor Structures Including a Nanocrystalline Core And Shell Embedded in a Matrix, incorporated herein by reference.

Core/shell nanoparticles comprising a semiconductor core and a semiconductor shell may be used in applications where high photoluminescence efficiency or quantum yield is desired. In such embodiments, the semiconductor shell can comprise a semiconductor having a higher bandgap energy than that of the semiconductor core. For example, a first Group 12-Group 16 semiconductor material such as CdSe can be present in the core and a second Group 12-Group 16 semiconductor material such as ZnS can be present in the shell. In other embodiments, the semiconductor shell can have good conduction and valence band offset with respect to the semiconductor core. In some embodiments, the conduction band can be higher and the valence band can be lower than those of the core. For example, composition of the core/shell nanoparticles may comprise a semiconductor core emitting energy in the visible region, such as CdS, CdSe, CdTe, ZnSe, ZnTe, GaP, InP, or GaAs, or the near IR region such as InP, InAs, InSb, PbS, or PbSe, and a semiconductor shell having a bandgap energy in the UV region such as ZnS, GaN, and magnesium chalcogenides such as MgS, MgSe, and MgTe. In some embodiments, the composition of the core/shell nanoparticles may comprise a semiconductor core emitting energy in the near IR region and the semiconductor shell having a bandgap energy in the visible region such as CdS or ZnSe. In some embodiments, the core comprises a metal sulfide such as CdS or ZnS; metal phosphide such as InP, GaP or AlP; a metal selenide such as CdSe, ZnSe or MgSe; or a metal telluride such as CdTe or ZnTe. In some embodiments, the shell comprises a metal sulfide such as CdS or ZnS; a metal phosphide such as InP, GaP or AlP; a metal selenide such as CdSe, ZnSe or MgSe; or a metal telluride such as CdTe or ZnTe.

In some embodiments, the shell comprises a multilayered shell having from two to five outer shells, an inner shell overcoating the core, and each outer shell overcoating the inner shell and outer shells. In some embodiments, the inner shell comprises ZnS and ZnSe, and the outer shell comprises ZnS. In some embodiments, the core/shell nanoparticles are core/shell quantum dots comprising InP/ZnS, InP/ZnSe, InP/ZnSe/ZnS, CdSe/CdS, CdSe/ZnS or CdSe/CdZnS. The thickness of the shell(s) can be selected to provide a quantum dot exhibiting a particular emission wavelength, quantum yield, luminescence stability or other photostability characteristic.

The Won article, cited above, explored the effects of different shell thicknesses and ligands on the electroluminescence from InP quantum dots. For the current systems, non-radiative quenching is diminished by the use of particle mixtures that tend to space the emitting nanoparticles from each other, and excess inhibition of energy transfer reduces desirable FRET from blue nanoparticles in the nanoparticle mixtures. For embodiments with blends of nanoparticles mixed together for dense deposition, the concern over non-radiative quenching becomes secondary due to separation of particles due to the presence of the particles of different sizes. The shells provided in commercial quantum dots are observed to provide good optical properties for the particle blends described herein.

### Scattering Nanoparticles

While for applications of particular interest, the primary active function for the ultimate patterned composition generally involves light emission at desired wavelengths, other non-emitting nanoparticles can contribute significant performance improvements based on light scattering to increase effective light path length through the material, as noted above. As exemplified herein, the inclusion of scattering nanoparticles as particulate additives into the material can be performed consistently with the ligand based direct patterning approach. The amounts of scattering particles can be adjusted to yield desired improvements in light output from luminescence. The scattering particles improve luminescence output even though they do not fluoresce by increasing absorption by the luminescent nanoparticles through increasing the effective path length of the stimulating light energy entering the material.

The luminescent nanoparticles can have different values of index of refraction relative to the fluorescing nanoparticles. Specifically, the scattering particles can have lower or higher indices of refraction relative to the luminescent nanoparticles. In general, scattering particles can be selected from a wide range of inorganic particles that have appropriate scattering of the incident light. In some embodiments, suitable scattering particles can comprise, for example, barium titanate (BaTiO₃), titanium oxide (TiO₂), zirconium oxide (ZrO₂), diamond, hafnium oxide (HfO), mixtures thereof, and the like, with relatively high index of refraction, or silicon oxide (SiO₂) with a relatively low index of refraction. For example, the difference in index between an InP thin film with index of refraction of 3.54 at 633 nm and TiO₂ (rutile) with an index of refraction of 2.87 at 633 nm is 0.67. For example, the difference in index between an InP thin film with index of refraction of 3.54 at 633 nm and BaTiO₃ with an index of refraction of 2.40 at 633 nm is 1.14. The difference in index between an InP thin film with index of refraction of 3.54 at 633 nm and SiO₂ with an index of refraction of 1.45 is 2.09. In embodiments in which the scattering particles are significantly larger than the luminescent nanoparticles, the number percent of scattering particles can be significantly less than the weight average values. With lower number average amounts of particles, the patterning can generally be effectively performed without surface modifying the scattering particles with radiation sensitive ligands. In some embodiments, the scattering particles are also surface modified with radiation sensitive ligands, as described further below.

While the particle sizes can overlap, scattering nanoparticles generally have a larger average diameter relative to the luminescent nanoparticles. As a result, number averages for the scattering nanoparticles generally are smaller in comparison with weight averages. The inorganic additives may be particles or nanoparticles, and may be substantially round nanoparticles and other shaped nanoparticles, such as nanorods or nanoplates. Suitable inorganic additives comprising particles or nanoparticles generally have an average particle diameter of up to about 500 nm, in other embodiments up to 200 nm., and in further embodiments up to 100 nm, where the average particle diameter is an average along the particles three principal axes. A person of ordinary skill in the art will recognize that additional ranges of average particle diameters within the explicit ranges above are contemplated and are within the present disclosure.

The inorganic scattering particles or nanoparticles may be surface modified with ligands non-covalently or covalently bound to a surface of the particles or nanoparticles. The ligands can be photoactive organic ligands, which are the same or similar to the photoactive ligands bound to the luminescent nanoparticles for patterning purposes. Since the number average of the scattering particles can be less than for the luminescent nanoparticles, effective patterning can be achieved with scattering particles that are not modified with photoactive organic ligands, but modifying scattering particles with photoactive organic ligands can provide potential further improvements in direct patterning approaches described herein. Ligands having one or more electron donating functional groups can be bound to a surface of the particles or nanoparticles by covalent or non-covalent binding. Useful ligands are described further in the next section, with appropriate consideration of ligand selection based on distinct particle composition.

An optical material for use in a down-converting pixel structure can have optionally from about 0.5 weight percent (wt %) to about 45 wt % scattering particles and in further embodiments from about 1 wt % to about 20 wt % scattering particles. A person of ordinary skill in the art will recognize that additional ranges of scattering particle concentrations within the explicit ranges above are contemplated and are in the present disclosure.

### Photoactive Organic Ligands

To provide for direct photo-patterning of the nanoparticle materials, photoactive organic ligands are bound to the nanoparticles such that the nanoparticles are surface-modified. Surface modification involves combining the nanoparticles with one or more photoactive organic ligands, and the photoactive organic ligands bind to the nanoparticles and modify the surface characteristics of the nanoparticles. A photoactive organic ligand binds to a surface of a nanoparticle in the sense that it is associated with, or attached to, the nanoparticle with sufficient stability for the nanoparticles to be suitable for their intended use. A photoactive organic ligand binds to a surface of a nanoparticle by being physically bound, for example, by absorption or adsorption, or by being chemically bound, for example, by covalent bonds or non-covalent bonds such as ionic bonds or hydrogen bonds.

The nanoparticles may also have non-photoactive ligands also. Some nanoparticles are provided by suppliers with ligands to inhibit agglomeration of the nanoparticles. Attachment of the photoactive ligands may displace some or all of the initial inert ligands, but it is possible that some of both types of ligands may remain. It is not particularly significant for the function of the photoactive ligands whether or not other inert ligands are also present.

Photoactive organic ligands useful for surface-modifying the nanoparticles can be described generally as comprising a linking group, a photoreactive group, and an activation group, wherein the photoreactive group is covalently bonded to both the linking group and the activation group, but the photoreactive group could also be the activation group. In other words, the activation group can also be the photoreactive group. Exemplified photoreactive groups herein are photocleavable groups, and the discussion herein focuses to some degree on photocleavable groups. Photoreactive groups alternatively can undergo reduction-oxidation reactions in respect to photoabsorption with associated internal rearrangements that result in the anticipated changes in solubility.

The linking group of the photoactive organic ligand coordinates or binds the ligand to the nanoparticle such as to the surface of the nanoparticle. The linking group includes a functional group that binds the photoactive organic ligand to a surface of a nanoparticle and is covalently bonded to the photocleavable group. Any suitable linking group may be used, as long as the activation group and photocleavable group of the organic ligand retain utility. For nanoparticles comprising semiconductor nanoparticles, the linking group can comprise an electron-donating group such as a hydroxyl, thiol, amine, phosphine, phosphine oxide, trialkoxy silanes, or carboxylic acid, any of which can be attached to the photocleavable group by a spacer moiety. Thiol functional groups are particularly suitable for many semiconductor nanoparticle surfaces, such as III-V materials, and these are exemplified herein. For metal oxide nanoparticles, hydroxyl (—OH), amine (NH₂), carbonyl (—COOH), phosphonyl (PO(OH)₂), trialkoxysilanes, mixtures thereof, and/or derivatives thereof functional groups can be desirable. Exemplary spacer moieties are generally hydrocarbon alkyl moieties such as —(CH₂)ₙ— where n=1-12, and may be linear or branched with optional heteroatoms, such as oxygen, nitrogen, or halides. An extensive discussion of functional groups for linking ligands to inorganic particles is found in Heuer-Jungemann et al., entitled “The Role of Ligands in the Chemical Synthesis and Applications of Inorganic Nanoparticles,” Chem. Rev. 2019, 119, 4819-4880, incorporated herein by reference.

For oxide nanoparticle compositions, which can be used for scattering particles, alternative linking groups may be desirable, such as silylating agents, which can be used to functionalize the particles with photoactive organic ligands. Useful silylating agents have the general formula [R—(CH₂)ₘ]ₙ—Si—X₍₃₋ₙ₎ wherein R is an organic photoactive group, (CH₂)ₘ is a linking group with m=1-5, X is a hydrolyzable group and n=0-2. Useful silylating agents also include alkoxy modified silanes having the general formula R¹R²R³—Si—R⁴, where R¹, R², R³ are alkoxy groups, which can hydrolyze and bond with the particles, and R⁴ is a group suitable for bonding to the surface of the particles or nanoparticles. Useful silylating agents also include silicates having trichlorosilicate (—SiCl₃) functional groups which can react with an hydroxyl group at the metal oxide particle surface by way of a condensation reaction.

The photoactive organic ligand comprises a photocleavable group that is covalently bonded to both the linking group and the activation group. Any suitable photocleavable group may be used, as long as the photoactive organic ligand can function as desired. The photocleavable group may comprise a bridging non-carbon atom along with an adjacent carbonyl group to provide a cleavable group that can dissociate at appropriate energies transferred from the activation group that include, for example, an amide, ester, acid anhydride, carbonate or carbamate group, or any organosulfur derivatives thereof, in which an oxygen or nitrogen is replaced by sulfur. Organosulfur photocleavable groups include, for example, thioester, dithioester, thioamide, O-thiocarbamate, S-thiocarbamate, and dithiocarbamate groups.

The photoactive organic ligand, in particular the activation group, absorbs radiation of an appropriate wavelength such that it undergoes a photochemical organic reaction which results in cleavage of the photocleavable group. The photocleavable group can receive radiation transferred from the activation group. Radiation of an appropriate wavelength is generally in the UV-visible region of the electromagnetic spectrum, for example, from about 200 nm to about 500 nm, or from about 250 nm to about 420 nm. A suitable photocleavable group may absorb radiation outside of the aforementioned ranges, and the absorption selectively can be tuned to a different wavelength by the activation group, as described below. A person of ordinary skill in the art will recognize that additional wavelengths or ranges of wavelengths within the explicit ranges above are contemplated and are within the present disclosure.

In general, the photochemical organic reaction may be a homolytic reaction, or more particularly, a photolytic reaction by which the photoactive organic ligand is broken down by photons absorbed by the photocleavable group, although in some embodiments, cleavage reactions may comprise reactions with ancillary molecules, such as atmospheric water. Upon absorption of radiation of an appropriate wavelength, the photocleavable group undergoes cleavage, which may involve hydrolysis with a reaction involving water possibly from the ambient atmosphere. The photocleavable group itself generally decomposes upon cleavage. The photocleavable group may fragment from both the linking group and the activation group, the photocleavable group or a portion of the group may remain covalently bonded to the linking group or the activation group, or portions of the photocleavable group may remain bonded to both the linking and the activation group. In the cases where the photocleavable group remains bonded, upon cleavage of the photoactive organic ligand, the photocleavable group may undergo a rearrangement with the group to which it remains covalently bonded.

Generally, an activation group is present within the photoactive organic ligand, which is usually not bound to a surface of the nanoparticles and is relatively more exposed to solvent, compared to any other portion of the ligand, when the ligand is bound to a surface of the nanoparticles and the corresponding surface-modified nanoparticles are dissolved or suspended in a suitable solvent. The activation group activates the photocleavable group in the sense that it is interacting with the photocleavable group and a major absorption peak of the photocleavable group is influenced by these interactions with the activation group. The activation group essentially can function as an antenna which allows one to enhance absorption of the radiation leading to photocleavage to increase the effective absorption cross section and cleavage for a given light fluence. The activation group can be selected to have a strong absorption for the selected patterning wavelength. The structure of the activation group relative to the photocleavable group should provide for good electronic overlap either through proximity or steric arrangement between the moieties. Aromatic rings generally provide strong UV absorption and can serve as UV activating groups.

Upon exposure to energy of an appropriate wavelength, the photoactive organic ligand undergoes photocleavage such that the activation group fragments from the ligand. The remaining portion of the ligand, including or not including some portion of the photocleavable group, forms a photochemically-modified ligand. The photochemically-modified ligand is bound to a surface of the nanoparticles, i.e., the linking group (with the possibility of additional desired moieties) of the photoactive organic ligand remains bound to a surface of the nanoparticles. As an example, as shown in Eqn. 1, photocleavage of the ligand having Formula IIa results in fragmentation to form thioglycolic acid and 4-amino-toluene. The linking group of ligand having Formula IIa is the anion of —CH₂—SH, and the linking group remains bound to a surface of the nanoparticles represented as M. Upon exposure and photocleavage, ligand having Formula IIa becomes the photochemically-modified ligand which is the thiolate of thioglycolic acid. As described further below, upon exposure and photocleavage of selected portions of a layer comprising the surface-modified nanoparticles described herein, the surface-modified nanoparticles become photochemically-modified nanoparticles in the selected portions.

To create contrast between the original ligand (such as Formula IIa) and the photocleaved product, the photochemically modified nanoparticles are designed to become more hydrophilic after photocleavage so they would be more soluble/dispersible in polar solvents, while the initial surface modified nanoparticles would be more hydrophobic so that they are more soluble/dispersible in organic or less polar solvents. This feature aims to create selective dissolution of the nanoparticles for material development.

The initial formulation of the ligand is designed specifically to display high solubility in less polar (or non-polar) organic solvents before photo-exposure. For the purposes of the solubility of the ligands, a non-polar organic solvent is generally defined as a type of solvent that has low partial charge or dipole moments, with dielectric constants often lower than about 15. Prominent examples of these solvents include, for example, chloroform, chlorobenzene, cyclohexane, diethyl ether, hexane, heptane, methylene chloride, pentane, pyridine, tetrahydrofuran, toluene, and xylene. The initial ligand design is optimized for solubility in these non-polar organic solvents or some combinations of these.

Upon exposure to the UV activation, the photocleavage removes a portion of the ligand, allowing for the nanoparticle to obtain a different functionality. As in Eqn. 1, the new ligand terminal group will likely have different properties and interact with the solvent in a different manner from the original ligand group (ie. Formulation IIa). The new terminal group is designed to have increased solubility in polar organic or aqueous solvents. For the purposes of the solubility of the ligands, a polar organic solvent is generally defined as a type of solvent that has high partial charge or dipole moments, with dielectric constants often lower than about 15. Polar solvents can be classified as protic or aprotic, depending on the presence of a dissociable hydrogen atom. Both protic and aprotic solvents are considered appropriate for the nanoparticle solubility of this structure. Non-protic polar organic solvents include dimethylformamide (DMF), cyclopentanone, cyclohexanone, 2-butanone, methyl acetate, ethyl acetate, propyl acetate, propylene carbonate, 4-methyl-2-pentanone and propylene glycol methyl ether acetate. Additionally, exemplary polar protic solvents include methanol, ethanol, isopropanol, and the like. Solubility in a polar organic solvent may be achieved within a combination of solvents as well. Aqueous solvents may also be used for solubilizing the exposed nanoparticle. In this situation, the aqueous solvent is defined as any solvent that is based on water. These solvents may also contain additives and may be classified as acidic, basic, ionic, or may contain surfactants. Examples of aqueous solution additives that may dissolve photo-exposed nanoparticles include, but are not limited to, tetramethylammonium hydroxide, sodium hydroxide, potassium hydroxide, triethylamine, sodium metasilicate pentahydrate, sodium borate decahydrate, octyl phenol ethoxylate, polysorbates, and sulfates.

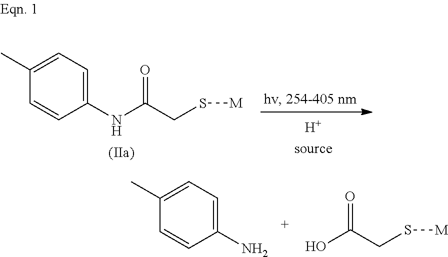

For an explicit example of this solubility contrast, refer to Eqn. 1. In this ligand formulation, the tolyl activation group benefit is two-fold: the aromaticity of the moiety is able to not only amplify the UV radiation to the photocleavage group, but also increase the solubility of nanoparticles surface-modified with Ligand IIa within the aforementioned nonpolar organic solvents. In this example, radiation having a wavelength of from about 254 nm to about 405 nm is applied to photoactive organic Ligand IIa bound to nanoparticle M, inducing a hydrolysis reaction driven by absorption of radiation, with water provided by water vapor in ambient air. After photocleavage within the thioglycolamide removes the aromatic toluidine group, the remaining thioglycolic acid is the primary functional group of the exposed nanoparticle. The new structure possesses a solubility that is unlike that of the original Ligand Ia: the thioglycolic acid terminated ligand displays a preferred solubility in more polar solvents (such as ethyl acetate) in contrast to the tolyl terminated ligand. This feature allows for selective dissolution of the nanoparticles, with exposed thioglycolic acid-terminated nanoparticles solubilizing in polar solvents while the unexposed tolyl-terminated nanoparticles remaining undissolved.

Ligand IIa is not the only ligand that is able to display these contrasting properties. In some embodiments, suitable photoactive organic ligands can be represented by, but not limited to, chemical structures of Formulas Ia and Ib:

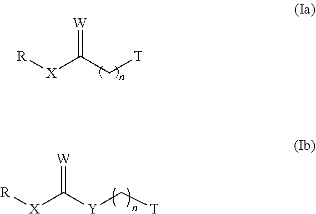

wherein —(CH₂)ₙ—T represents the linking group; X—C(W)— or X—C(W)—Y represents the photocleavable group; and R represents the activation group. In some embodiments, for the linking group, n=1-5 and T comprises a hydroxyl, thiol, amine, phosphine, phosphine oxide, trialkoxy silyl, carboxylic acid, or a salt of any of the aforementioned. In some embodiments, for the photocleavable group, X can comprise O, NH, N(R) such as N(Me) or N(Et), or S; W can comprise O or S; and Y can comprise O, NH, N(R) such as N(Me) or N(Et), or S.

For some embodiments for the activation group, R comprises a group having unsaturation, but any group may be used as long as the photoactive ligand can function as desired. In some embodiments, R may comprise a monovalent alkyl or divalent alkylene group comprising a saturated or unsaturated hydrocarbon group, and which may be linear or branched, cyclic or acyclic. Particular examples include C₁-C₂₀ alkyl groups, e.g., derived by reaction using oleic acid, stearic acid and/or palmitic acid, unsaturated C₄-C₂₀ alkylene groups, e.g., derived by reaction using omega-3, -6 or -9 fatty acids.

For some embodiments for the activation group, R may comprise a monovalent or polyvalent aromatic group covalently linked to the photocleavable group, either directly or indirectly with a saturated or unsaturated group comprising a hydrocarbon group with optional heteroatom functionality. The monovalent or polyvalent aromatic group may comprise a hydrocarbon group such as a phenyl, benzyl, biphenyl, naphthyl, anthracenyl, fluorenyl, phenanthrenyl, azulenyl, phenalenyl, pyrene, perylen, or chrysene group. A monovalent or polyvalent aromatic group may comprise a heterocyclic aromatic group including an oxygen-, nitrogen- or sulfur-containing heterocycle group. Examples of heterocyclic aromatic groups include those derived from furan, oxazole, isoxazole, isothiazole, indone, pyridine, pyridazine, pyrimidine, pyridone, pyrazine, pyrrole, pyrrolidinone, purine, quinoline, isoquinoline, imidazole, thiophene, thiazolium. Any of the monovalent or polyvalent aromatic groups may be covalently linked to the photocleavable group at any suitable position, for example, a naphthyl group may be linked to the photocleavable group at the 2- or 3-position of the naphthyl group. Selection of the activation group is generally guided at least in part by the absorption spectrum of the group such that it provides a desired strong absorption at the desired wavelength.

The monovalent or polyvalent aromatic group as activation group R may be unsubstituted or substituted with substituents, such as C₁-C₄ alkyl; C₁-C₄ alkoxy; C₁-C₄ alkyl or aryl substituted primary, secondary or tertiary (cationic) amino; C₁-C₄ alkylthiol; halide such as F, Cl, Br or I; carboxyl or carboxylate such as —COOH, —CH₂COOH; C₁-C₄ alkyl or aryl ester or acyl; C₁-C₄ alkyl or aryl sulfonamide; C₁-C₄ alkyl or aryl thiosulfonamide; cyano; nitro; sulfo or sulfonyl groups, or combinations or mixtures thereof. Substitution of the monovalent or polyvalent aromatic groups may be at one or more positions of a given ring structure, for example, an anthracenyl group may be substituted at the 1-, 2- or 10-positions; or the 1-, 2- and 10-positions, with any of the aforementioned groups.

Any of the monovalent or polyvalent aromatic groups described above may be fused to one or more aromatic groups including any of those listed above. For example, an imidazole ring may be fused to a phenyl ring to give a benzimidazole group. For another example, an imidazole ring may be fused to a pyrimidine ring to give a purine group.

Alkyl or alkylene groups include groups having ethylenic unsaturation such as α,β-unsaturated carbonyl compounds such as α,β-unsaturated carboxylic acids, esters and amides; α,β-unsaturated ketones and aldehydes; and corresponding α,β-unsaturated sulfur analogs thereof. The alkyl or alkylene groups can be linear or branched, cyclic or acyclic, and substituted or unsubstituted groups, and wherein hetero atoms may optionally be present in the group.

Monovalent aromatic groups include C₆-C₂₀ aromatic groups such as phenyl, benzyl, biphenyl, and the like, and which can be unsubstituted or substituted with any number of substituents. Monovalent aromatic groups may be substituted with groups including C₁-C₄ alkyl; C₁-C₄ alkoxy; C₁-C₄ alkylthiol; F; Cl; Br; I; CN; NO; COOH or salts thereof; C₁-C₄ carboxyl; —CH₂COOR₁ wherein R₁ is an alkyl or aryl group; NH₂; NHR₂ or NR₂R₃ wherein R₂ and R₃ are independently alkyl or aryl groups; —CH; NHR₄ or —CH₂NR₄R₅ wherein R₄ and R₅ are independently alkyl or aryl groups; sulfo; sulfonyl; and wherein R₁-R₅ can independently comprise acyl or carbonyl groups, sulfonamide groups, heterocyclic groups including substituted and unsubstituted 5- and 6-membered oxygen-containing or heterocyclic amines or thiophenes such as furfuryl, piperidine, morpholine, pyrrolidine or piperazine.

Polyvalent aromatic groups include groups having two to five aromatic rings which may or may not be fused ring systems. Examples of polyvalent aromatic groups include naphthalene, fluorene, anthracene, phenanthrene, phenalene, pyrene, perylene, chrysene, and the like. The polyvalent aromatic groups can be unsubstituted or substituted with any number of groups including C₁-C₄ alkyl; C₁-C₄ alkoxy; C₁-C₄ alkylthiol; F; Cl; Br; I; CN; NO₂; COOH or salts thereof; C₁-C₄ carboxyl; —CH₂COOR₁ wherein R₁ is an alkyl or aryl group; NH₂; NHR₂ or NR₂R₃ wherein R₂ and R₃ are independently alkyl or aryl groups; —CH₂NHR₄ or —CH₂NR₄R₅ wherein R₄ and R₅ are independently alkyl or aryl groups; sulfo; sulfonyl; and wherein R₁-R₅ can independently comprise acyl or carbonyl groups, sulfonamide groups, heterocyclic groups including substituted and unsubstituted 5- and 6-membered oxygen-containing or heterocyclic amines or thiophenes such as furfuryl, piperidine, morpholine, pyrrolidine or piperazine.

Specific examples of R include 4-tolyl; 4-tert-butylphenyl; 2-naphthyl; 2-anthracenyl; 2-fluorenyl and 4-(4-ethylphenyl)phenyl; 4-nitrophenyl; 4-nitrobenzyl; 2-nitro-5-methylbenzyl; 4,5-dimethoxy-2-nitrobenzyl; and 2,3-dimethoxy-2-nitrobenzyl.

Examples of suitable photoactive organic ligands include ligands having chemical structures of Formulas IIa-IIf:

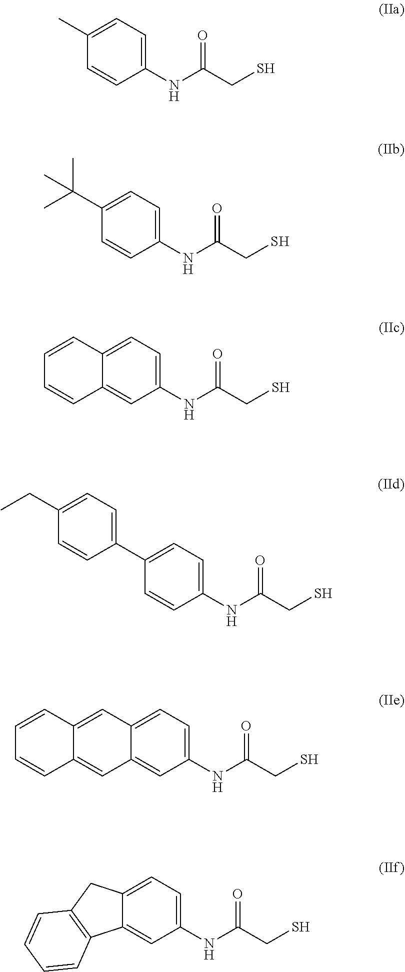 [SMILES: Cc1ccc(NC(=O)CS)cc1 ; CC(C)(C)c1ccc(NC(=O)CS)cc1 ; O=C(CS)Nc1ccc2ccccc2c1 ; CCc1ccc(-c2ccc(NC(=O)CS)cc2)cc1 ; O=C(CS)Nc1ccc2cc3ccccc3cc2c1 ; O=C(CS)Nc1ccc2c(c1)-c1ccccc1C2]

Examples of suitable photoactive organic ligands include ligands having chemical structures of Formulas IIIa-IIIc:

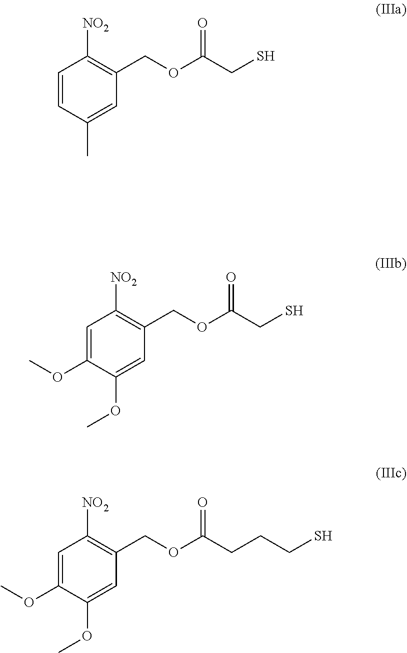 [SMILES: Cc1ccc([N+](=O)[O-])c(COC(=O)CS)c1 ; COc1cc(COC(=O)CS)c([N+](=O)[O-])cc1OC ; COc1cc(COC(=O)CCCS)c([N+](=O)[O-])cc1OC]

Examples of suitable photoactive organic ligands include ligands having chemical structures of Formulas IVa-IVc:

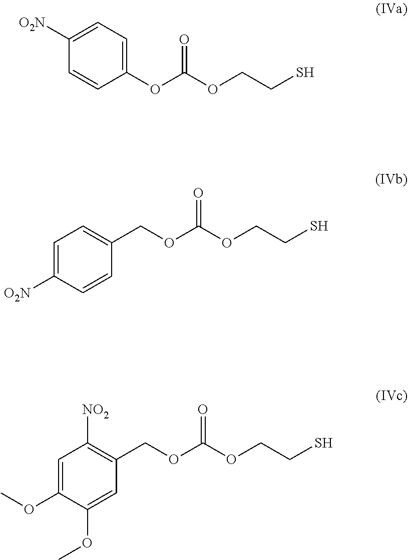 [SMILES: O=C(OCCS)Oc1ccc([N+](=O)[O-])cc1 ; O=C(OCCS)OCc1ccc([N+](=O)[O-])cc1 ; COc1cc(COC(=O)OCCS)c([N+](=O)[O-])cc1OC]

The photoactive organic ligands suitable for use as described herein may be synthesized, for example, by conventional organic synthetic methods. Synthetic organic strategies for making the ligands can be found in introductory or advanced organic synthesis textbooks, for example: Smith, Michael B., March's advanced organic chemistry: reactions, mechanisms, and structure, (hereinafter Smith) John Wiley & Sons, 2020; and Caron, Stéphane, ed. Practical synthetic organic chemistry: reactions, principles, and techniques, (hereinafter Caron) John Wiley & Sons, 2020. New and updated synthetic methods can be found in literature, for example: Muramatsu, Wataru, Tomohiro Hattori, and Hisashi Yamamoto. “Amide bond formation: beyond the dilemma between activation and racemisation.” Chemical Communications 57.52 (2021): 6346-6359; and in review articles, for example: Yan, Ming, Yu Kawamata, and Phil S. Baran. “Synthetic organic electrochemical methods since 2000: on the verge of a renaissance.” Chemical reviews 117.21 (2017): 13230-13319. A brief summary of known synthetic strategies is presented below but is not intended to be a complete summary of all methods which can be used to synthesize the photoactive organic ligands. Of course, with respect to practical methods with good yields and convenient reactants can be selected based on these teachings and routine experimentation by a person of ordinary skill in the art.

Some photoactive organic ligands can be made by coupling two precursors to form the ligand represented by Formula Ia as shown in Eqn. 2. In this example, precursors Va and Vb are coupled to form a ligand of Formula Ia wherein the photocleavable group comprises an ester, amide, thioester, dithioester or thioamide. Precursor Va may comprise an alcohol, amine or thiol wherein X=O, N or S, respectively, and R is an activation group as described above. Precursor Vb may comprise an ester, carboxylic acid, acyl chloride or acid anhydride wherein Z=OR′, OH, Cl or OR″, respectively, with R′=C₁-C₄ alkyl and R″=—C(═O)(CH₂)ₙT; T is a coordinating group as described above, and P is a protecting group as described herein. Reaction conditions such as temperature, ratio of equivalents of precursors may be varied as described in Smith or Caron to yield photoactive organic ligands wherein W=O or S and X=O, NH, NR₂ or S.

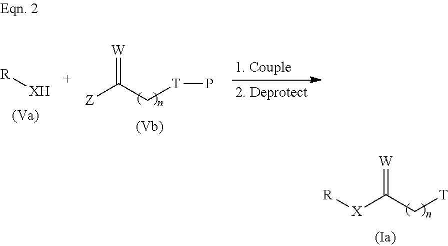

Photoactive organic ligands of Formula Ia with W=O and X=O can be prepared by transesterification of precursor Vb, wherein Z=OR′ and R′ comprises an alkoxy group of a C₁-C₄ alkyl, with precursor Va, in the presence of an acid or base. Photoactive organic ligand of Formula Ia with X=O can also be prepared by esterification of precursor Vb, in which Z=OH, with precursor Va, in the presence of an acid as proton source or a Lewis acid that coordinates to the carbonyl oxygen. In either of these examples, an activated ester of precursor Vb may be formed prior to the addition of precursor Va. For example, the activated ester of precursor Vb may be formed by reacting the ester or carboxylic acid form of precursor Vb with dicyclohexyl carbodiimide (DCC), ethyl (dimethylaminopropyl) carbodiimide, N-hydroxysuccinimide or hydroxybenzotriazole. Catalysts such as 4-(dimethyl-amino)pyridine (DMAP) or coordinating metals may be added to facilitate coupling of precursor Va with the activated form of precursor Vb.

Photoactive organic ligands of Formula Ia with W=O and X=O can also be prepared by acylation with precursor Vb as the acylating agent. For example, precursor Vb may be in the form of an acid chloride with Z=Cl, or in the form of an acid anhydride with Z=OR″ and R″=—C(═O)(CH₂)ₙT or —C(═O)(CH₂)ₙTP.

Photoactive organic ligands of Formula Ia with W=O and X=NH or NR₂ can be prepared by reacting the amine of precursor Va with an acid chloride, acid azide, ester or acid anhydride of precursor Vb, wherein Z=Cl, N₃, OR′ or OR″ with R″=—C(═O)(CH₂)ₙT or —C(═O)(CH₂)ₙTP. Reaction conditions can be found in Smith or Caron, cited above. The ester form of precursor Vb wherein Z=OR′ can be an activated ester as described above. The carboxylic acid of precursor Vb wherein Z=OH can be used to form an activated ester which can then be reacted with precursor Va with X=NH or NH₂.

Photoactive organic ligands of Formula Ia with W=O and X=S can be prepared by several known routes. For example, the alkali metal salt of precursor Va with X=S can be reacted with the acid chloride of precursor Vb wherein Z=Cl. For another example, halide displacement of the halide form of precursor Va with an alkali metal salt of a thiocarboxylic acid as precursor Vb can be used. Photoactive organic ligands of Formula Ia with X=S can also be prepared by condensation of the thiol of precursor Va wherein X=S with the carboxylic acid of Vb wherein Z=OH in the presence of a dehydrating agent.

For photoactive organic ligands of Formula Ia with W=S, the photocleavable group can be a thioamide or dithioester with X=NH, NR₂ or S. Thioamides and dithioesters can be prepared by several methods, such as by treating the corresponding amide with a phosphorus sulfide, by using Lawesson's reagent, or by reaction of the corresponding nitriles with hydrogen sulfide. Other methods of thioamide bond formation are described in Smith or Caron, cited above.

For some synthetic methods, the coordinating group T may be protected with protecting group P as shown in Eqn. 2. The protecting group can be selectively removed in a separate step when desired. Many protecting groups are known. For T=OH, silyl ethers such as trimethylsilyl, or other groups such as tetrahydropyranyl, benzyl or tosyl may be used. For T=NH or COOH, carbamate, acetyl or benzoyl groups may be used. For T=NH, protecting groups such as carbobenzyloxy or acetyl groups may be used.

For photoactive organic ligands where T=SH, the thiol group can be protected by synthesizing the ligand as the corresponding disulfide. For example, two equivalents of nucleophile R—X where X=OH or NH₂ can be coupled with dithiodiglycolic acid to form disulfide VIa as shown in Eqn. 3. The disulfide can be isolated and the corresponding thiol formed in situ during surface modification of the nanoparticles. In some cases, depending on the particular nucleophile, the corresponding thiol can be isolated in a separate step before surface modification of the nanoparticles. The corresponding thiol can be formed by cleavage of the disulfide bond using known methods as described in Smith or Caron, cited above. For example, a reducing agent such as sodium borohydride can be used to convert the disulfide to the thiol form.

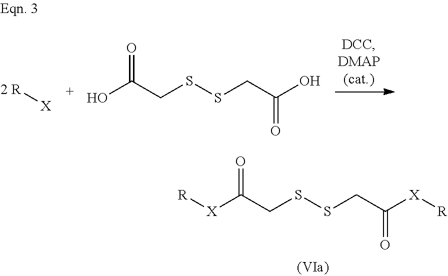

Photoactive organic ligands of Formula Ib can be made using synthetic organic methods as described in Smith or Caron, cited above. For example, photoactive organic ligands of Formula Ib with a carbonate as photocleavable group, wherein W, X and Y=O, can be prepared by phosgenation in which the corresponding alcohol or phenol of the activation group is reacted with phosgene, or by oxidative carbonylation in which the corresponding alcohol or phenol of the activation group is reacted with carbon monoxide and an oxidizer. Another synthetic route to forming photoactive organic ligands of Formula Ib wherein W, X and Y=O includes transesterification in which one equilibrium exchange drives the desired carbonate as described above for the formation of photocleavable groups comprising esters.

Photoactive organic ligands of Formula Ib with a carbamate or urea as the photocleavable group can be synthesized using a variety of synthetic organic methods. For example, photoactive organic ligands of Formula Ib with a carbamate or urea as photocleavable group can be synthesized by phosgenation whereby phosgene or a phosgene precursor is reacted with an amine and an alcohol to form the corresponding carbamate, or with two amines to form the corresponding urea. Photoactive organic ligands of Formula Ib with a carbamate as the photocleavable group can also be synthesized by equilibrium exchange whereby an alcohol of the activation group or linking group is reacted with a corresponding urea. Other useful synthetic organic methods include formation of carbamates and ureas through formation of activated ester carbonates which can be isolated or reacted in situ with the corresponding alcohol or amine as described above for the formation of esters and amides. Photoactive organic ligands of Formula Ib may require the use of protecting groups as described above for ligands of Formula Ia.

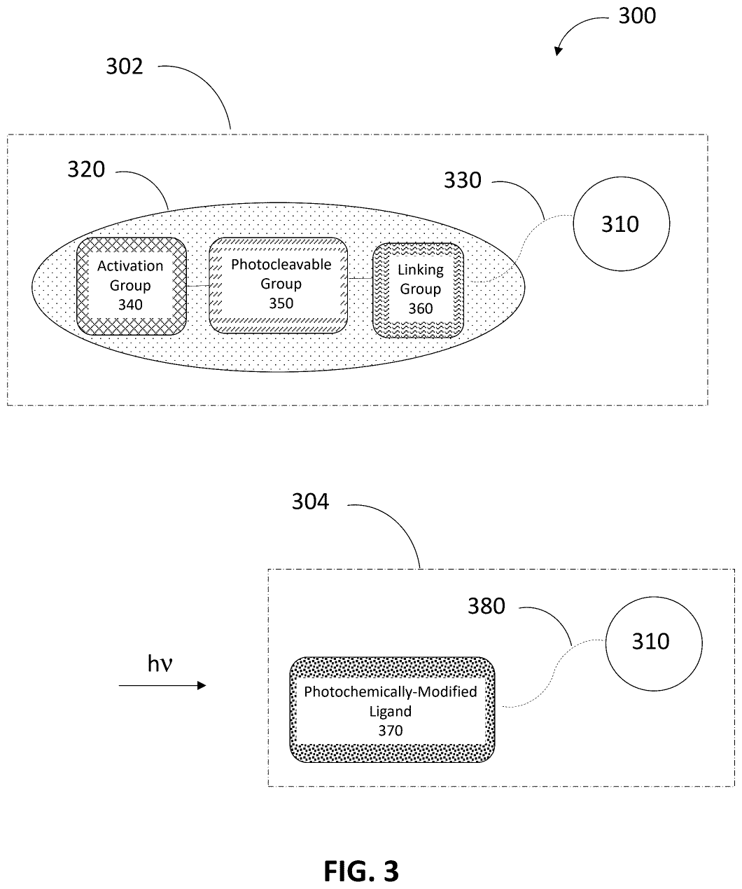

FIG. 3 is a schematic conceptual representation showing a change in functional groups of an exemplary photoactive organic ligand as a result of the ligand undergoing a photochemical reaction. Reaction scheme 300 shows surface modified nanoparticle 302 comprising photoactive organic ligand 320 coordinated to nanoparticle 310 by coordinating bond 330. Photoactive organic ligand 320 comprises activation group 340 covalently bonded to photocleavable group 350 which is covalently bonded to linking group 360. Radiation hv is absorbed by activation group 340, and possibly photocleavable group 350, and photocleavable group 350 cleaves such that photochemically modified ligand 370 is formed and is coordinated to nanoparticle 310 by coordinating bond 380. In general, activation group 340 and photocleavable group 350 can be the same group. Coordinating bonds 330 and 380 may or may not be the same or similar coordinating bonds. Surface modified nanoparticle 302 becomes photochemically surface modified nanoparticle 304. In this example, photoactive organic ligand 320 forms photochemically modified ligand 370 that is different in terms of size and shape. Photochemically modified ligand 370 has a solubility different from that of photoactive organic ligand 320.

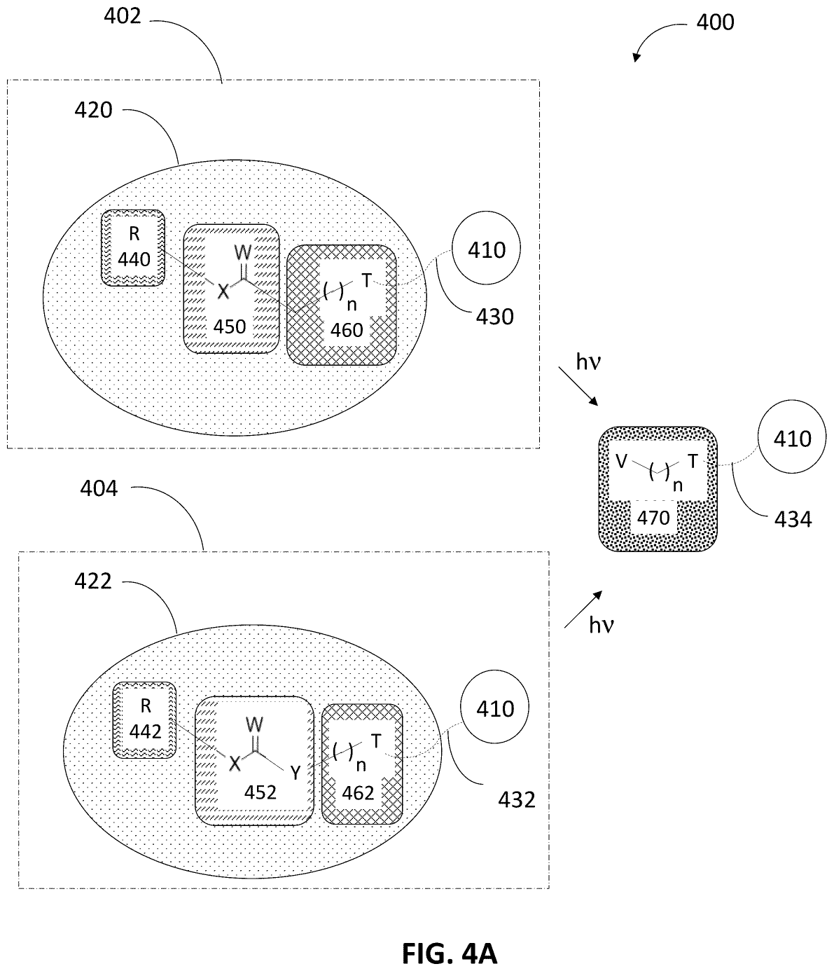

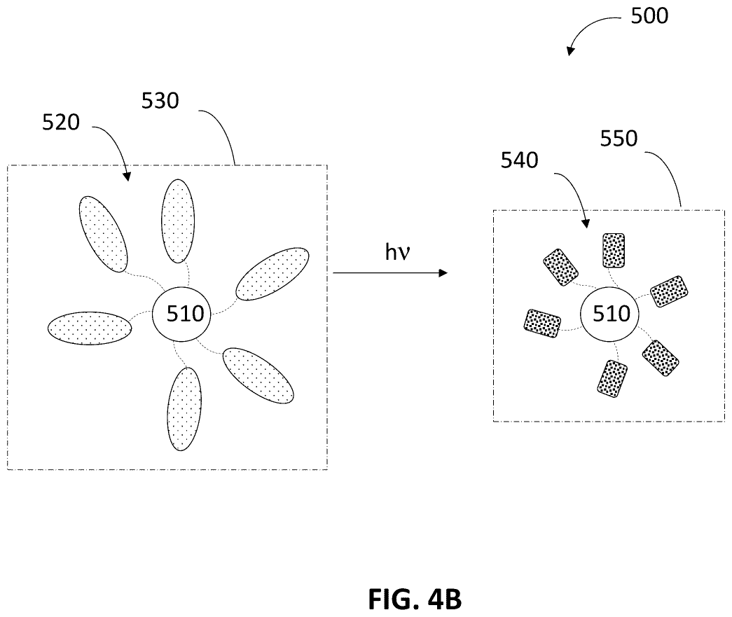

FIG. 4 is a schematic representation showing exemplary photochemical reactions of the photoactive organic ligands described herein. Reaction scheme 400 shows surface modified nanoparticle 402 comprising photoactive organic ligand 420 coordinated to nanoparticle 410 by coordinating bond 430. Photoactive organic ligand 420 has the chemical structure ligand Ia and includes activation group 440 covalently bonded to photocleavable group 450 which is covalently bonded to linking group 460. Radiation hv is absorbed by photocleavable group 450 which cleaves such that photochemically modified ligand 470 is formed and is coordinated to nanoparticle 410 by coordinating bond 434. Coordinating bonds 430 and 434 may or may not be the same or similar coordinating bonds.

Reaction scheme 400 also shows surface modified nanoparticle 404 comprising photoactive organic ligand 422 coordinated to nanoparticle 410 by coordinating bond 432. Photoactive organic ligand 422 has the chemical structure ligand IIa and includes activation group 442 covalently bonded to photocleavable group 452 which is covalently bonded to linking group 462. Radiation hv is absorbed by activation group 442, and possibly photocleavable group 452, and photocleavable group 452 cleaves such that photochemically modified ligand 470 is formed and is coordinated to nanoparticle 410 by coordinating bond 434. Coordinating bonds 432 and 434 may or may not be the same or similar coordinating bonds.

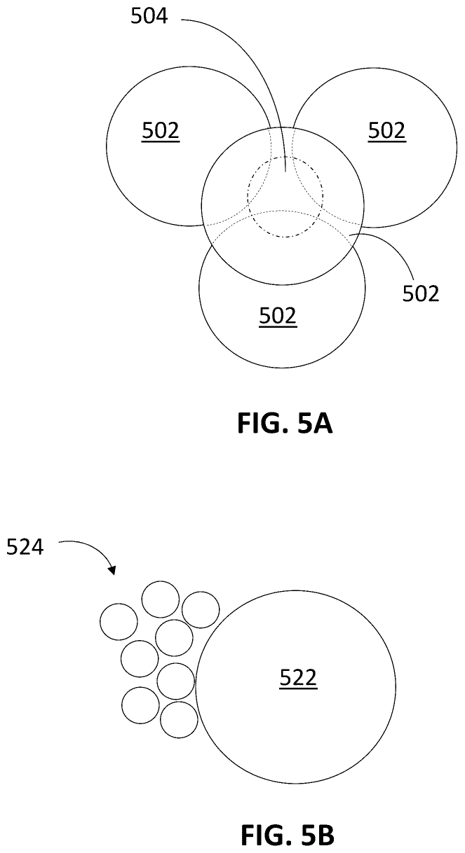

FIG. 5 is a schematic conceptual representation showing an exemplary change in surface functionality of nanoparticles that is imparted by photochemical reactions of the photoactive organic ligands as described in FIG. 3. Reaction scheme 500 shows surface modified nanoparticle 530 comprising nanoparticle 510 coordinated to photoactive organic ligands 520. Radiation hv is absorbed by an activation group, and possibly a photocleavable group of ligand 520 which cleaves such that photochemically modified ligand 540 is formed and is coordinated to nanoparticle 510. In this example, photochemically surface modified nanoparticle 550 is different from surface modified nanoparticle 530 in terms of overall shape, size and solubility.

### Preparation of Surface-Modified Nanoparticles, Coating Solutions

The nanoparticles can be surface-modified with any suitable amount of photoactive organic ligand depending on the desired performance required for the surface-modified nanoparticles. The design of the ligands provides a functional group that can associate with a reasonable binding affinity to the particle surface and may form a covalent bond. The photoactive organic ligand can replace and/or supplement any non-active ligands on the nanoparticle surface to inhibit agglomeration. The photoactive organic ligands are also effective to inhibit agglomeration. The photoactive organic ligands can be dispersed in a compatible solvent for blending with dispersed nanoparticles. The conditions then allow for the binding of the photoactive organic ligands with the nanoparticles to form surface modified nanoparticles. The dispersions of the surface modified nanoparticles can then be used to prepare coating solutions for forming coatings onto a surface for subsequent patterning.

The amount of photoactive ligand bound to the surface can be limited by the coverage over the surface area of the particle. With this constraint, less ligand can be used if sufficient patterning efficacy is obtained, and other process issues can be considered in selecting a desired amount of photoactive ligand. In some embodiments, the weight ratio of photoactive organic ligand to nanoparticle ranges from about 1:1 to about 1:1000. In some embodiments, the weight ratio of photoactive organic ligand to nanoparticle ranges from about 1:2 to about 1:750, in other embodiments from about 1:3 to about 1:600, or from about 1:4 to about 1:500. The weight of the ligand can be evaluated by thermogravimetric analysis, in which the ligand is removed thermally to leave the thermally stable inorganic particles. A person of ordinary skill in the art will recognize that additional ranges of weight ratios within the explicit ranges above are contemplated and are within the present disclosure.

In general, the nanoparticles can be synthesized, such as using known processes, or they can be purchased form a suitable supplier. The nanoparticles are typically produced or obtained as a solution in some original solvent, such as toluene or heptane. As used herein, the concepts of solution or dispersion and associated terminologies are used interchangeably with no consideration to potential distinctions. The nanoparticles may be used as received or synthesized, or they may be isolated and subsequently dispersed at a desired concentration in a desired solvent which can be the same or different from the original solvent. For example, quantum dots may be provided by some commercial suppliers as a solution in toluene, and acetone can be added to destabilize the solution, followed by centrifugation whereby the quantum dots are isolated as a pellet. The pellet can then be redispersed in toluene or other solvent to some desired concentration, which may be greater than the concentration of the quantum dots as received. For example, nanoparticles received as a solution of about 20 to about 50 wt %, may be isolated as pellets as described above, and then redissolved to provide a solution of about 5 to about 30 wt %.

The surface-modified nanoparticles may be prepared by combining the nanoparticles and photoactive organic ligand in a suitable solvent and stirring for an appropriate amount of time. The solvent generally provides for solubility of the photoactive organic ligand as well as the nanoparticles. The ligand binding can generally be performed at room temperature, although other reasonable temperatures can be used as desired. The amount of time can be selected to provide desired bonding. In general, suitable binding time for association of the ligands with the particles surfaces can be from about 2 minutes to about 24 hours, in further embodiments from about 5 minutes to about 12 hours and in other embodiments from about 7 minutes to about 6 hours. A person of ordinary skill in the art will recognize that additional ranges of times and nanoparticle concentrations within the explicit ranges above are contemplated and are within the present disclosure. The resulting solution can be referred to as an ink or coating solution.

In some embodiments, additives may be added to the coating solutions used to form the coated substrates. Useful additives include organic additives such as compounds with C₁-C₁₆ straight-chained or branched hydrocarbon groups having zero to three electron donating functional groups such as hydroxy; primary, secondary or tertiary amino; thiol; alkylthiol; carboxy; alkyl ester; alkyl glycol ether; primary, secondary or tertiary phosphines; or combinations thereof. The C₁-C₁₆ straight-chained or branched hydrocarbon groups may be saturated or unsaturated hydrocarbons, or they may be cyclic hydrocarbon groups. For example, the organic additives may comprise octadecene, butylamine, oleyl amine, n-decanethiol, oleic acid, propylene glycol methyl ether acetate, trioctylphospine, or proplyene carbonate.

Additives that may be added during or after surface modification of the nanoparticles include inorganic additives. Useful inorganic additives include salts such as chloride salts, for example, zinc chloride or sodium chloride. For example, organic additives may comprise octadecene, butylamine, oleyl amine, n-decanethiol, oleic acid, propylene glycol methyl ether acetate, trioctylphospine, or proplyene carbonate. The organic or inorganic additives can be used in any useful amount, for example, less than about 10 volume %, less than about 8 volume %, less than about 5 volume %, or less than about 2 volume % of the ink or coating solution.

### Coated Substrates and Preparation for Patterning

The coating solutions described in the previous section can be applied to a substrate and the coatings can be subsequently patterned if it is desirable to provide a pattern for formation of distinct domains along the surface. Based on the introduction of the photoactive organic ligands, direct patterning can be accomplished from the coating. The patterning process not only does not use a polymer binder in the patterning process but could be inhibited from patterning if a polymer binder interferes with the direct patterning process. In addition, the coated film generally has a low organic content to provide desirable particle packing. The sample is irradiated with suitable radiation to cleave the photoactive groups to form a latent image on the surface. The radiation patterned surface has differential properties for the irradiated and the non-irradiated portions that provide a basis for selective development of the pattern to form a physical structured surface.

The substrate can comprise any suitable material. For a structured substrate, for example with layers, the top surface provides the relevant interface for processing and can be considered the substrate for practical purposes. Rigid or flexible substrates may be employed. In some embodiments, the substrate surface can be desirably flat and smooth. In some embodiments related to effective down-conversion to convert light from an initial wavelength, the substrate can have a transmittance of at least about 50%, at least about 80%, or at least about 90%, for light in the visible region of the electromagnetic spectrum (400 nm to 700 nm). A person of ordinary skill in the art will recognize that additional minimum values for transmittance within the explicit ranges above are contemplated and are within the present disclosure.

The substrate may comprise any reasonable material, and generally the substrate is transparent. Suitable substrates include glass, such as soda-lime glass, barium/strontium-containing glass, lead glass, aluminosilicate glass, borosilicate glass, barium silicate glass or quartz. In some embodiments, the substrate may comprise a transparent polymeric film, such as polycarbonate, a polyacrylic copolymer, polyethylene terephthalate, polyethersulfide, polysulfone, polyimide and appropriate copolymers. Substrates can comprise a plurality of layers and can comprise protective layers. The substrate may also comprise a plurality of active light-emitting devices, for example an array of InGaN light-emitting diodes or an array of OLED pixels. Generally, the substrate can be selected to meet desired properties for the ultimate product.

The coating solutions can be applied to the substrate using any reasonable coating or printing process. For example, suitable processes include spin coating, knife edge coating, spray coating, gravure printing, screen printing, or the like. The initial deposition may impose some rough patterning with more fine patterning followed by the photolithography described herein. The wet thickness can be determined by the desired dry thickness of the coating. The wet thickness generally can be selected based on the concentration of the coating solution, which in turn generally is influenced by the rheology of the coating solution consistent with the selected coating process. Generally the wet thicknesses can be from about 1 micron to about 1 millimeter, in further embodiments form about 1.5 microns to about 100 microns and in other embodiments form about 2 microns to about 50 microns.

The wet coating can be dried for further processing. Drying can be performed by exposing the coating to evaporation of solvent into the ambient atmosphere. If desired heat can be applied to speed the drying process. The temperature and heating times can be selected based on the solvent and coating thickness. Heat can be applied using heated vapor, placement in an oven, using infrared light or other suitable heating modality.

The layer of surface-modified nanoparticles can have any suitable thickness. The dry layer thickness is generally selected based on the particular applications. For light conversion applications, generally a thickness is selected to convert the wavelength of incident light into a desired wavelength with little of the incident light being transmitted. Desirable optical density of the resulting layers are discussed below. Also, the selected thickness of the layer may depend on how radiation patterning is carried out as described below. For example, the thickness of the layer of surface-modified nanoparticles and the source and/or intensity of the radiation being used to form the latent image may need to be adjusted together. In some embodiments, the layer has a thickness that is greater than the depth of the radiation being applied during patterning. For example, the dry layer may have a thickness of from about 1 μm to about 100 μm, in some embodiments from about 1 μm to about 20 μm, and in further embodiments from about 1.5 μm to about 15 μm. A person of ordinary skill in the art will recognize that additional ranges of wet and dry thicknesses within the explicit ranges above are contemplated and are within the present disclosure.

The coating generally comprises a low organic content. The organic content can comprise only ligands and possibly organic cleavage products from patterning. Additional organic components can be process aides, polymers or other additives to provide desired properties. In general, the total organic components are less than 10 wt %, in further embodiments no more than 2 weight percent, in other embodiments no more than about 1 wt %, and in additional embodiments no more than about 0.1 wt %. Organic components refer to non-volatile compositions. The amount of organic constituents can be determined by thermogravimetric analysis. The exemplified embodiments include no organic components other than the ligands and potentially cleavage products from the ligands. A person of ordinary skill in the art will recognize that additional ranges within the explicit ranges above are contemplated and are within the present disclosure.

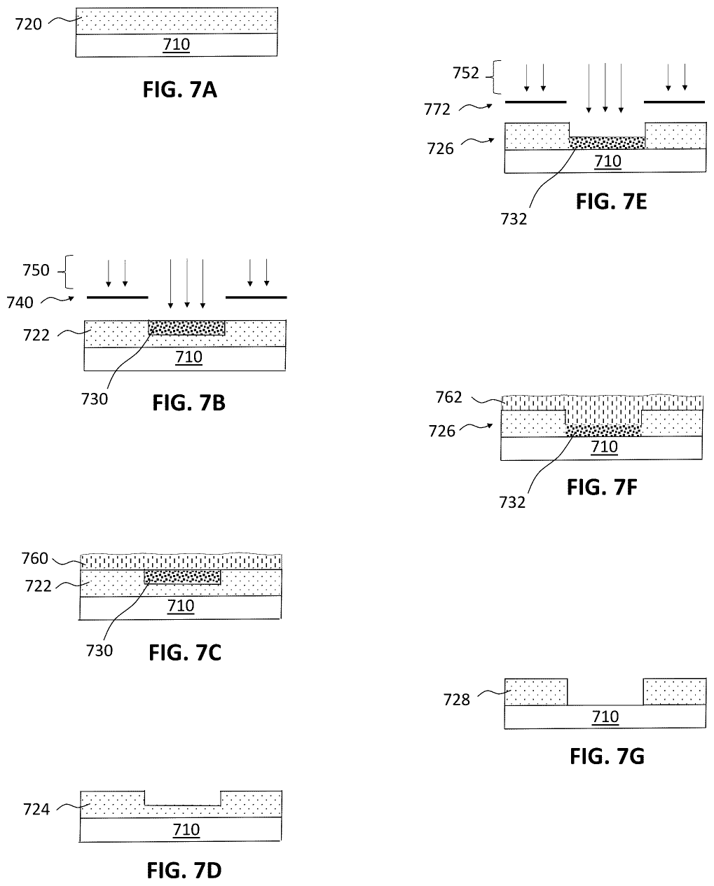

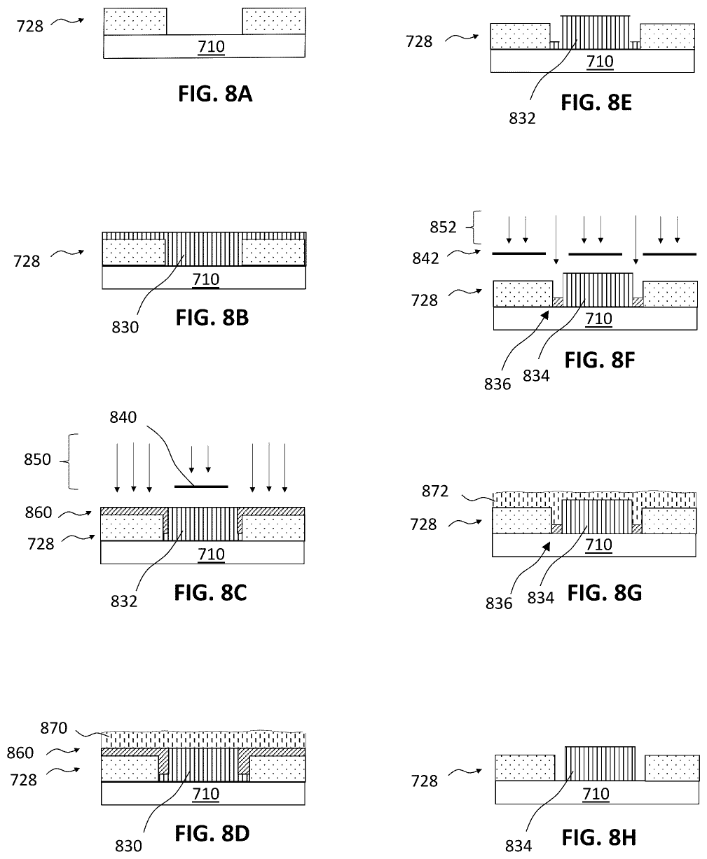

Formation of a latent image involves irradiation with patterned radiation. Patterned radiation can be supplied by irradiation through a suitable mask or by scanning focused radiation, such as a focused laser beam across the coating. The films can be irradiated using photolithography processes with exposure of UV light ranging in wavelength of 230-365 nm and can be adapted for use with commercial UV photolithography equipment. Other suitable radiation sources can be used, such as 193 nm ArF laser light, 436 nm (Hg G-line) or other suitable light. This process leaves a chemically altered surface in the exposed areas (FIG. 7). The films can then be selectively developed with select solvents and can be demonstrated as a positive or negative resist depending on the solvent selected (FIG. 8). More details of the formation of the latent image are provided below. The latent image is then developed to form a physical pattern adapted for the desired use.

### Formation of Dense Deposits of Quantum Dots and Blends of Particles

To obtain desired high optical densities of as deposited nanoparticles, the nanoparticles can be deposited without a polymer binder. The desirable ligands described herein allow for the resulting nanoparticle deposits to form essentially dense deposits limited by particle packing constraints. The ligands can repress both formation of agglomerates as well as repulsive forces that may limit packing. In general, the deposition approaches can involve any suitable deposition compatible with the particles and solvents, as described above. Solvent then is removed to leave the prepared surface ready for patterning. Particle blends can be used effectively to both increase particle density and corresponding increase in optical density. Through the blending of smaller sized particles, such as smaller blue quantum confined nanoparticles with larger red quantum confined nanoparticles and/or green quantum confined nanoparticles, and/or through blending with larger scattering particles, the size discrepancy can facilitate a larger closest packing density, decrease non-radiative relaxation through separation of similar luminescent nanoparticles from each other, while allowing effective energy transfer from the blue nanoparticles to the red or green nanoparticles to increase external quantum efficiency.

To prepare dispersions for deposition, the nanoparticles are prepared with the selected ligands as described above. Then, the concentration of the dispersions can be adjusted as desired, and the solvents can be similarly adjusted as desired. If the dispersions comprise a blend of particles, these can be formed from a blend of separate dispersions formed with the same solvent or with compatible solvent, where the solvent may or may not comprise a blend of liquids. The concentrations of particles generally can be adjusted to yield appropriate dispersion rheology for the selected deposition approach as described above, based on the blend of nanoparticles.

For a mixture of blue nanoparticles with red nanoparticles and/or with green nanoparticles, especially quantum confined nanoparticles, the blue nanoparticles can have a significantly smaller diameter. Thus, blue quantum confined nanoparticles may fit in the interstices of the closest pack structure of the red/green quantum confined nanoparticles, which allows a corresponding increase in the density of the resulting layer. As exemplified below, the presence of blue quantum confined nanoparticles is observed to reduce non-radiative loss while providing an energy transfer from the blue quantum confined nanoparticles to the lower frequency emitting quantum confined nanoparticles. The observed overall effect is to improve the observed optical density and simultaneously increase the quantum efficiency. As a result, a thinner layer of quantum dots can be used to achieve the desired color emission.

The dispersions of the blended nanoparticles can comprise selected relative amounts of the different color nanoparticles. Since the nanoparticles included to provide for resonance energy transfer to the emitting nanoparticles provide several functions, such as increasing packing density, the relative concentrations can be selected accordingly. Also, based on the different particle sizes, the weight ratios are different from the number ratios. In general, the relative weight percents of blue nanoparticles can be from about 5 wt % to about 95 wt %, in more embodiments from about 10 wt % to about 90 wt % and in further embodiments form about 20 wt % to about 75 wt % blue nanoparticles relative to the weight of the longer wavelength, e.g., red and/or green, emitting nanoparticles. The number ratios can be correspondingly estimated using the average diameters of the respective nanoparticles and the corresponding particle volumes. A person of ordinary skill in the art will recognize that additional ranges of relative amounts of blue nanoparticles within the explicit ranges above are contemplated and are within the present disclosure.

With respect to scattering particles, in general, scattering can result from changes in index of refraction. Scattering can be useful by increasing the path length of light through the material to amplify the optical effects. Effective scattering can generally be induced by somewhat larger scattering particles, and particle size disparity similarly can assist with packing density. The index of refraction differences can depend on the composition of the quantum dots. For example, indium phosphide has an index of refraction of 3.55 for around visible wavelengths, while other emitting compounds may have different, for example lower, indices. Nanoparticle indices of refraction are generally considerably higher than organic systems. Thus, a standard high scattering material, such as barium titanate, which has an index of refraction of about 2.4, may have a lower index relative to the quantum dots, although it has a significantly higher index than organic compositions. A change in index of refraction in either direction can provide effective scattering if the nanoparticles have a sufficiently different refractive index. Examples are provided below with barium titanate used with indium phosphide based quantum confined nanoparticles.

The presence of scattering particles physically displaces luminescent nanoparticles from a coating thereby reducing their numbers, so there is a tradeoff in the inclusion of scattering particles. The scattering particles though may provide some packing advantage for due to the different particle sizes and separation of like colored nanoparticles by the scattering particles, which reduces non-radiative decay. In general, it is desirable to use larger scattering particles, and these can have average particle sizes from about 25 nm to about 500 nm, in further embodiments from about 30 nm to about 350 nm, and in additional embodiments from about 40 nm to about 200 nm. With respect to relative amounts of scattering particles, it has been found that relatively high scattering particle loading can result in improved values of optical density and quantum yield. In the coating materials, the composition can comprise from about 5 wt % to about 70 wt %, in further embodiments from about 7 weight percent to about 65 weight percent and in additional embodiments from about 10 weight percent to about 60 wt %. Due to the larger particle sizes of the scattering particles relative to quantum confined nanoparticles, the number concentration is proportionally smaller, and relative number percents can be approximately calculated using the average diameters/particle sizes and the resulting particle volumes. A person of ordinary skill in the art will recognize that additional ranges of average particle sizes and weight percent loadings within the explicit ranges above are contemplated and are within the present disclosure.

For a particular coating, the selected particles, following attachment of desired ligands, are blended with a selected amount of solvent as a solvent. The concentration and resulting rheology of the dispersion generally is selected based on the desired deposition approaches. Formation of coating solutions is described above, and the parameters of these coating solutions relating to solvents and percent solids apply equally here as if explicitly copied here.

### Radiation Patterning

The formation of a physical pattern is driven by radiation delivered with a corresponding pattern. In general, radiation patterning is carried out using any suitable type of radiation, or any suitable source of radiation, as long as the desired patterned substrate can be formed from the coated substrate. The irradiation results in chemical changes in the irradiated material that results in a contrast between the irradiated material and the non-irradiated material that allows for differential solubility. To the extent that the full effects of patterning are not achieved with a single irradiation step, multiple irradiation steps over the same or different pattern can be performed, generally with an intervening development step.

In some embodiments, radiation patterning of the coated substrates described herein employs electromagnetic radiation having a desired wavelength or range of wavelengths within the UV-visible region, i.e., from about 100 nm to about 750 nm. In some embodiments, the radiation may have a wavelength or range of wavelengths from about 250 nm to about 420 nm, or from about 250 nm to about 370 nm. As used herein, radiation having a desired wavelength generally refers to monochromatic light of a specific wavelength, with a narrow bandwidth of wavelengths being what is actually observed. A person of ordinary skill in the art will recognize that additional ranges of radiation within the explicit ranges above are contemplated and are within the present disclosure.

The wavelength or range of wavelengths used to form the patterned substrate can depend on any number of factors. At the very least, energy delivered to the layer to be patterned needs to cause photolytic cleavage of the photoactive organic ligand as described above. It is generally practical to utilize commercially available sources of UV-visible radiation such as an Hg lamp g-line or LED equivalent source at 436 nm, an HG lamp h-line or LED equivalent source at 405 nm, an Hg lamp i-line or LED equivalent source at 385 or 365 nm, a krypton fluoride laser at about 248 nm, or an argon fluoride laser at 193 nm. The wavelength or range of wavelengths employed can affect the resolution of the patterned layer, and the radiation source may be selected accordingly.

The amount of electromagnetic radiation can be characterized by a fluence or dose which is obtained by the integrated radiative flux over the exposure time. Suitable radiation fluences can be from about 50 mJ/cm² to about 9000 mJ/cm², in further embodiments from about 75 mJ/cm² to about 7500 mJ/cm² and in further embodiments from about 100 mJ/cm² to about 5000 mJ/cm². A person of ordinary skill in the art will recognize that additional ranges of radiation fluences within the explicit ranges above are contemplated and are within the present disclosure.

Radiation is generally delivered according to a selected pattern. Being delivered according to a selected pattern can comprise delivering radiation through a mask. Radiation can be delivered without a mask, for example, computer software may be used to provide profiles for delivering the radiation imagewise, across the layer being patterned, in accordance with a selected pattern. A latent image formed by patterning with radiation can be developed using different solvents such that the resulting patterned substrate comprises a negative or positive resist or photoresist. After forming the latent image, the coating is developed to selectively remove a portion of the coating. If the non-irradiated material is removed to leave the irradiated material, this is called negative tone development, and if the irradiated material is removed to leave the non-irradiated material, this is termed positive tone development. The patterning process described herein can be successfully used for either negative tone or positive tone development. Commercial photoresists are generally designed to perform either negative tone or positive tone development. In some embodiments, development can be conducted in a solution of a hydrocarbon solvent and 0-25% oleic acid. In some embodiments, aromatic solvents, such as toluene, may be useful. Suitable solvents may include, but are not limited to; methanol, ethanol, other alcohols, DMF, cyclopentanone, cyclohexanone, 2-Butanone, ethyl acetate, propyl acetate, methyl acetate, propylene carbonate, 4-methyl-2-pentanone, propylene glycol methyl ether acetate, and water.

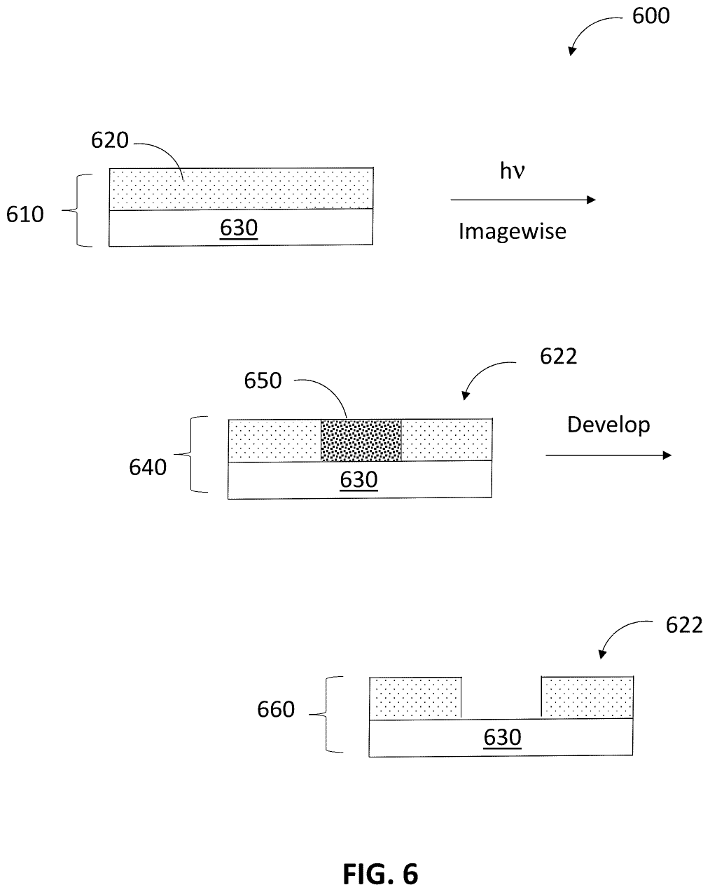

FIG. 6 is a schematic illustration showing radiation patterning and development of a layer of quantum dots surface modified with the photoactive organic ligands described herein. Exemplary method 600 illustrates formation of positive photoresist. Coated substrate 610 comprising a layer of surface modified nanoparticles 620 is disposed on substrate 630. The surface modified nanoparticles are surface modified with photoactive organic ligand having a photocleavable group capable of absorbing radiation of an appropriate wavelength, hv, which is applied imagewise to layer 620. In areas of layer 620 to which the radiation is applied, the photocleavable group absorbs the radiation and undergoes photochemical reaction in which the group is cleaved such that the photoactive organic ligand forms a photochemically modified organic ligand. Imaged coated substrate 640 is formed and comprises unexposed portions 622 and exposed area 650 comprising nanoparticles surface modified with photochemically modified organic ligand. Thus, coated layer 620 becomes a layer including a latent image. Imaged coated substrate 640 is then developed with a suitable solvent to remove exposed area 650. Imaged or patterned substrate 660 is formed and comprises unexposed portions 622 disposed on substrate 630.

FIGS. 7A-7G are schematic illustrations which together convey an exemplary method for forming the positive photoresist shown in FIG. 7G. FIG. 7A shows layer of surface modified nanoparticles 720 disposed on substrate 710. The surface modified nanoparticles are surface modified with photoactive organic ligand having a photocleavable group capable of absorbing radiation in the red region of the visible spectrum. FIG. 7B shows radiation emitted from a source (not shown) and represented by arrows 750. Mask 740 is disposed above layer of surface modified nanoparticles 720 such that the radiation is partially blocked by the mask and partially emitted through the mask. In areas of layer 720 exposed to the radiation, the photocleavable group absorbs the radiation and undergoes photochemical reaction in which the group is cleaved such that the photoactive organic ligand forms a photochemically modified organic ligand. Latent image 730 is formed in the exposed area and is surrounded by unexposed areas 722.

FIG. 7C shows a next step in the method in which latent image 730 and unexposed areas 722 are in contact with developer 760. Latent image 730 comprising nanoparticles surface modified with photochemically modified organic ligand is removed by the developer to form imaged layer 724 comprising unexposed areas or regions. FIG. 7D shows the unexposed areas or regions as a layer in cross sectional view, which illustrates exposure to a depth less than that of layer 720 before exposure. FIG. 7E shows radiation emitted from a source (not shown) and represented by arrows 752. Mask 742 is disposed above layer of surface modified nanoparticles 724 such that the radiation is partially blocked by the mask and partially emitted through the mask. In areas of layer 724 exposed to the radiation, the photocleavable group absorbs the radiation and undergoes photochemical reaction in which the group is cleaved such that the photoactive organic ligand forms a photochemically modified organic ligand. Latent image 732 is formed in the exposed area and is between unexposed areas 726. FIG. 7F shows a next step in the method in which latent image 732 and unexposed areas 726 are in contact with developer 762 which may or may not be the same as developer 760. Latent image 732 comprising nanoparticles surface modified with photochemically modified organic ligand is removed by the developer to form imaged layer 728 comprising unexposed areas or regions as shown in FIG. 7G.

FIGS. 8A-8H are schematic illustrations which together convey an exemplary method of positive and negative patterning used to form the photoresist shown in FIG. 8H. FIG. 8A shows imaged layer 728 disposed on substrate 710. FIG. 8B shows a layer of surface modified nanoparticles 830 disposed on imaged layer 728, where the surface modified nanoparticles in layer 830 exhibit emission in the green region of the visible spectrum. FIG. 8C shows radiation emitted from a source (not shown) and represented by arrows 850. Mask 840 is disposed above layer of green emitting surface modified nanoparticles 830 such that the radiation is partially blocked by the mask and partially emitted through the mask. In areas of layer 830 exposed to the radiation, the photocleavable group absorbs the radiation and undergoes photochemical reaction in which the group is cleaved such that the photoactive organic ligand forms a photochemically modified organic ligand. Latent image 860 is formed in the exposed areas and is adjacent unexposed area 832.

FIG. 8D shows a next step in the method in which latent image 860 and unexposed area 832 are in contact with developer 870. Latent image 860 is removed by the developer to such that unexposed area 832 remains as shown in FIG. 8E.

FIG. 8F shows radiation emitted from a source (not shown) and represented by arrows 852. Mask 842 is disposed above unexposed area 832 such that the radiation is partially blocked by the mask and partially emitted through the mask. In areas of unexposed area 832 exposed to the radiation, the photocleavable group absorbs the radiation and undergoes photochemical reaction in which the group is cleaved such that the photoactive organic ligand forms a photochemically modified organic ligand. Latent image 836 is formed in the exposed areas and is adjacent unexposed area 834. FIG. 8G shows a next step in the method in which imaged layer 728, unexposed area 834 and latent image 836 are in contact with developer 872 which may or may not be the same as developer 870. Latent image 836 is removed by the developer such that unexposed area 834 remains as shown in FIG. 8H.

As described further below, for color conversion applications, it can be desirable to achieve a certain amount of absorption of the stimulating light to provide for the target color output through removal of the stimulating light of the initial color, generally blue, and increasing the intensity of the emitted light, generally green or red. To achieve this desired performance, the layer of luminescent nanoparticles generally has a suitable thickness. With respect to the direct photopatterning approach, effective development involves penetration of the photopatterning radiation, e.g., ultraviolet light, through the layer. With practical radiation intensities, the photopatterning radiation may not penetrate sufficiently through the entire layer thickness, which is dictated to a significant degree by the application specifications. If the layer of nanoparticles is too thick for effective patterning through the entire layer at a desired fidelity, following development, a portion of the layer may be present at the locations of the pattern where material was removed. Once the initial development is performed, a portion of the patterning material is removed, so a subsequent irradiation step over the same pattern is directed to the lower portion of the irradiated material. In this way, a subsequent patterning step over the same pattern removes a second quantity of material to correspondingly increase the depth of removed material such that the patterning process can be completed. A third or additional patterning steps can be performed over the same pattern to complete the patterning process if needed to remove the target material. Of course, further patterning over different irradiation patterns can be used to provide other effects.

### Displays and Display Devices

The patterned substrates or films can be used in a wide range of displays and display devices such as color displays that emit a plurality of color light selectively and generally include self-addressed pixels or a display-wide backlight. The color display in which the patterned substrates or films can comprise an organic electroluminescent (EL) device, a light emitting diode (LED) device, an organic light emitting diode (OLED), a micro-light emitting (microLED) device, a quantum dot EL LED (ELQD) device, or an inorganic EL device. The patterned substrates or films can be used with light sources such as a cold cathode tube, a fluorescent lamp, an incandescent lamp or the like. The displays generally comprise a combination of pixels of the primary colors; blue, green and red. The three primary colors can be used to display any colors for visual perception including white light-based on the perception of mixed colors as an intermediate color. The perceived color spectrum can be evaluated by various accepted color scales, and the CIELAB Color Space is one accepted and commonly used standard. Commercial spectrometers can be purchased that evaluate CIELAB Color Space parameters.

When structures with deposits of luminescent nanoparticles are used for color conversion, it is desirable for the layer of luminescent nanoparticles to absorb essentially all of the incident light. The relative amounts of transmitted light relative to the incident light can be expressed in the context of the optical density. The optical density (OD) can be expressed as the base 10 logarithm of the intensity of incident light (I₀) divided by the intensity of the transmitted light (Iₜ), OD=log₁₀(I₀/Iₜ). For color conversion applications, it can be desirable for the OD with respect to the incident light be at least 1.5, in further embodiments at least about 1.75 and in some embodiments 1.9. At an OD of two, one percent of the incident light is transmitted. At higher values of OD, light conversion is more effective because the emitted light has little of the incident color. The overall light output can be evaluated under the CIELAB color space, which can be evaluated by some commercial spectrophotometers. A person of ordinary skill in the art will recognize that additional ranges of OD values within the explicit ranges above are contemplated and are within the present disclosure.

With the use of luminescent nanoparticles, another property of interest is the quantum efficiency. The external quantum efficiency (EQE) of nanoparticles can be measured as the number of photons emitted divided by the number of photons incident. As used herein, quantum efficiency (QE) refers to external quantum efficiency. With a higher quantum efficiency, fewer particles may be needed to produce a desired output, assuming the same absorption. Thus, it is desirable to have strong absorption and a high quantum efficiency. A related measure is the photoluminescent quantum yield (PLQY), which is the number of emitted photon divided by the absorbed photons. Values are reported in the Examples for PLQY.

For the present nanoparticle layers, the PLQY is calculated as described below in the examples. The inclusion of a significant number of scattering particles is found to significantly increase the PLQY. With the quantum confined nanoparticles described herein packed into a dense layer, the PLQY can be at least about 50%, in further embodiments at least about 52%, in other embodiments at least about 55%, in additional embodiments at least about 57.5% and in other embodiments from about 60% to about 75%. A person or ordinary skill in the art will recognize that additional ranges of quantum efficiency within the explicit ranges are contemplated and are within the present disclosure.

Several design improvements can work in conjunction to improve the emission output for color conversion embodiments, such as those using quantum confined nanoparticles. The deposition and patterning approaches that avoid the use of a polymer matrix provide for deposition of densely packed nanoparticles. The blending of the luminescent nanoparticles with smaller nanoparticles can provide for denser particle packing. If the smaller nanoparticles absorb preferentially higher energy light, these nanoparticles can perform energy transfer to the emitting luminescent nanoparticles while also physically spacing the emitting luminescent nanoparticles to reduce non-radiative decay. The inclusion of larger scattering particles can increase packing density, reduce non-radiative energy decay and increase the effective path length of the incident light by scattering the light through the system.

### EXAMPLES

### General Materials and Methods

### Preparation of Surface-Modified Nanoparticles

Ligands were synthesized using standard organic coupling techniques, as described in the description above, employing N—N′-dicyclohexylcarbodiimide (DCC) and optionally N,N′-dimethylaminopyridine (DMAP) in organic solvent at room temperature. Ligands having a thiol group for binding to the surface of the nanoparticles were synthesized using dithioglycolic acid to form the corresponding disulfide which was then isolated and characterized. In some examples, as described in the examples below, the disulfide form of the ligand was used to surface modify the nanoparticles. In some examples, the disulfide bond of the ligand in the disulfide form was cleaved with a reducing agent such as sodium borohydride to form the ligand which was then isolated as a solid. The ligand could be used to surface modify the nanoparticles.

Concentrated solutions of nanoparticles were prepared as follows. A solution of the nanoparticles in an original solvent was obtained from a supplier, and the nanoparticles were precipitated from the original solvent by adding a solvent to destabilize the dispersion. The sample of precipitated nanoparticles was centrifuged, and upon removal of solvents, the nanoparticles were isolated as a solid pellet. The solid pellet was then taken up in a desired solvent to obtain a solution of the nanoparticles at a desired concentration in the desired solvent for further processing. In a typical procedure, nanoparticles (2.4 mL@15 mg/mL in toluene) were precipitated using acetone or methanol, and the resulting sample was centrifuged at 4200 rpm for 15 minutes to form a solid pellet, and the solvent was decanted away from the pellet. The solid pellet was taken up in 0.25 mL of toluene to a concentration of about 150 mg/mL.

The nanoparticles were surface-modified with ligands as follows. A solution of the disulfide ligand (ligand isolated as the disulfide) was prepared by dissolving the disulfide ligand in a solvent known to be miscible with that used to prepare the concentrated solution of nanoparticles. The disulfide ligand solution and the concentrated solution of nanoparticles were combined and stirred at room temperature for about an hour. A destabilizing solvent was added to precipitate the surface modified nanoparticles. The sample of precipitated surface modified nanoparticles was centrifuged and upon removal of solvents by decanting, the surface modified nanoparticles were isolated as a solid pellet. The solid pellet was then taken up in a desired solvent to obtain a solution of the surface modified nanoparticles at a desired concentration. In a typical procedure, a solution of the disulfide ligand in chloroform was prepared at a concentration of about 40 mg/mL, and this solution was combined with a solution of the nanoparticles in toluene at a concentration of about 150 mg/mL, such than the ratio of nanoparticles to ligand was about 1:1 by weight. After stirring at room temperature for about an hour, the surface modified nanoparticles were precipitated using methanol, and the resulting sample was centrifuged at 4200 rpm for 20 minutes to form a solid pellet, and the supernatant decanted from the pellet. The solid pellet was taken up in chlorobenzene to a concentration of about 50 wt % and stirred for an hour to form an ink formulation of the surface modified nanoparticles.

### General Photopatterning

Ink formulations comprising the surface-modified nanoparticles were blade coated in a glove box onto glass slides. The blade height was set to 60 μm and the top of the blade coater was set to 60° C. Approximately 60 μL of an ink formulation was pipetted into the blade coater interfaced with the glass slide to form a meniscus in the reservoir of the blade coater. The blade was moved across the glass slide at a rate of about 0.2 m/s to form a film. The coated glass slide was allowed to dry for about 5 minutes before being removed from the coater. The coated glass slides were then removed from the glove box and softbaked on a hotplate set at about 115° C. to about 135° C. for 3-5 minutes. The resulting dried coated samples were cut into squares measuring approximately 1 cm×1 cm using a glass cutter.

A sample square was positioned in a photolithography box equipped with a UV light source (193-405 nm) such as a UV LED light source (365 nm) from Thorlabs, Inc. Photopatterning was carried out by placing a coated sample inside a photolithography box with the coated side up, and placing a photomask on top of the coated sample. The box was closed and the UV light turned on to expose the coating selectively at dosages specified in the Examples. The exposed sample was developed by placing the exposed sample into an organic solvent and agitating for about 5 minutes to remove the exposed areas. The patterned sample was removed from the organic solvent and dried with compressed air. If additional patterning was employed, the patterned sample was subjected to one or more additional exposure/development cycles.

### Measurements

Optical measurements were made using a homebuilt instrument. For Reflectance mode measurements, used for PLQY measurements, the sample was placed inside a 6 inch integrating sphere available from Labsphere, Inc. and excited though an entrance port by a 455 nm fiber-coupled LED from Thorlabs, Inc. that was filtered by a 455 nm bandpass filter. The excitation and emission signals were collected through a collection port and measured with an Ocean HDX CCD spectrophotometer from Ocean Insight, Inc. and blazed for 365-900 nm detection range. For Transmission mode measurements, used for EQE measurements, the sample was placed outside of the integrating sphere entrance port and the 455 nm excitation source was passed through the sample and collected inside the integrating sphere.

By using the data collected in Reflectance mode, photoluminescence quantum yield (PLQY) as a percent was calculated according to Eqn. 4:

$$PLQY ( \% ) = \frac{emission photon c ount}{absorbed count of excitation photons} \times 100 \qquad Eqn . 4$$

Optical density was evaluated as the log₁₀(T), where T is the transmittance along the incident direction. By using the data collected in Transmission mode, the thickness at an optical density of 2, OD2, was calculated according to Eqn. 5:

$$Thickness at OD 2 = \frac{2 * thickness}{optical density} \qquad Eqn . 5$$

By using the data collected in Transmission mode, the External Quantum Efficiency (EQE) as a percent was calculated according to Eqn. 6:

$$EQE ( \% ) = \frac{emission photon count}{incident count of excitation photons} \times 100 \qquad Eqn . 6$$

### Example 1—Synthesis of the Disulfide of Photoactive Organic Ligand IIf

Dithiodiglycolic acid (0.502 g, 2.75 mmol, 1 eq.), DCC (1.250 g, 6.1 mmol, 2.2 eq.), and 2-aminofluorene (0.649 g, 6.1 mmol, 2.2 eq.) were added to a 50 mL round bottom flask followed by the addition of chloroform (20 mL) and a stir bar. The reaction was loosely covered and allowed to stir at room temperature for 24 h at 40° C. A change in color and a cloudiness was observed within the first hour of the reaction indicating the formation of urea by-products. The reaction mixture was purified by filtration of urea solids from the chloroform solution. Recrystallization from boiling toluene was carried out to obtain the disulfide of photoactive organic ligand IIf.

### Example 2—Synthesis of Photoactive Organic Ligand IIf from Corresponding Disulfide

The disulfide of photoactive organic ligand IIf (0.050 g, 0.098 mmol, 1 eq.) was added to a dried 25 mL round bottom flask along with a stir bar and stirring started. Sodium borohydride (0.011 g, 0.3 mmol, 3 eq.) was added to a separate vial along with 10 mL of methanol and mixed till dissolved. The sodium borohydride solution was added in portions to the solution in the round bottom flask followed by stirring at room temperature for 3 hours. Sodium borohydride is a reducing agent introduced to cleave the disulfide bond. Following the reaction, saturated aqueous sodium chloride was added to the round bottom flask and mixed for 30 minutes. The product was extracted with a liquid-liquid extraction using chloroform as the organic phase. The organic phase was dried with magnesium sulfate, filtered, and the solvent evaporated to leave a solid powder. The powder was reconstituted into a 40 mg/mL solution.

### Example 3—Synthesis of the Disulfide of Photoactive Organic Ligand IIIb

Dithiodiglycolic acid (0.221 g, 1.2 mmol, 1 eq.), DCC (0.500 g, 2.4 mmol, 2.2 eq.), 4,5-dimethoxy-2-nitrobenzyl alcohol (0.568 g, 2.6 mmol, 2.2 eq.) and DMAP (0.065 g, 0.53 mmol, 20 mol %) were added to a dried 50 mL round bottom flask followed by the addition of chloroform (15 mL) and a stir bar. The reaction was loosely covered and allowed to stir at room temperature for 24 h. A change in color and a cloudiness was observed within the first hour of the reaction indicating the formation of urea by-products. The reaction mixture was purified by filtration of urea solids from the chloroform solution. Recrystallization from boiling toluene was carried out to obtain the disulfide of photoactive organic ligand IIIb.

The synthesis of the disulfide of photoactive organic ligand IIIb was repeated with DMAP at 5 mol %. Dithiodiglycolic acid (3.5 g, 19 mmol, 1 eq.), DCC (8.0 g, 39 mmol, 2 eq.), 4-5-dimethoxy-2-nitrobenzyl alcohol (9.1 g, 43 mmol, 2.2 eq.), and DMAP (0.12 g, 1.0 mmol, 5 mol %) were added to a dry 500 mL round bottom flask followed by the addition of dichloromethane (305 mL) and a stir bar. The reaction was loosely covered and allowed to stir at room temperature for 24 h. A change in color and a cloudiness is typically observed within the first hour of the reaction indicating the formation of urea by-products. The reaction mixture was purified by the filtration of the urea solids from the solution and recrystallization from boiling toluene to obtain the disulfide of photoactive ligand IIIb.

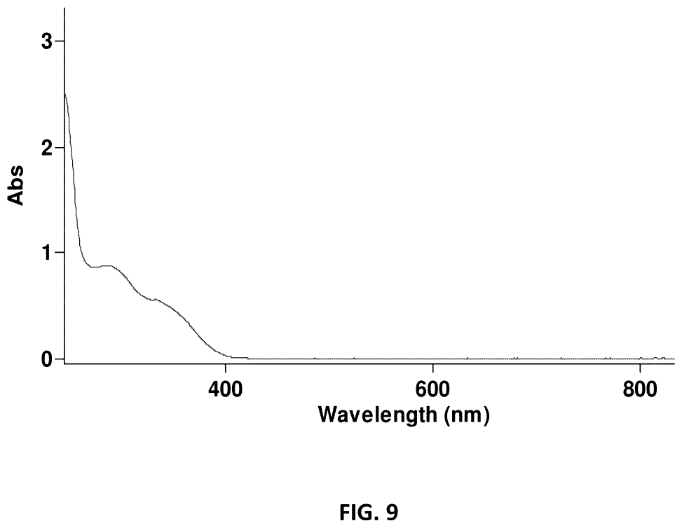

Characterization of the disulfide of photoactive organic ligand IIIb: Melting point 142.4° C. ¹H NMR (500 MHz, CDCl₃) δ_{H} (ppm) 7.71 (s, 2H), 7.05 (s, 2H), 5.56 (s, 4H), 4.00 (s, 6H), 3.96 (s, 4H), 3.69 (s, 4H). 7.68 (s, 2H), 7.05 (s, 2H), 5.53 (s, 4H), 3.97 (s, 6H), 3.93 (s, 4H), 3.67 (s, 4H). ¹³C NMR (125 MHz, CDCl₃) δ_{C} (ppm) 168.7, 153.7, 148.4, 139.8, 126.5, 110.5, 108.3, 64.3, 56.7, 56.5, 41.3. The absorption spectrum is shown in FIG. 9.

### Example 4—Synthesis of the Disulfide of Photoactive Organic Ligand IIIc

Dithiodiglycolic acid (2.3 g, 10.0 mmol, 1 eq.), DCC (4.0 g, 19.4 mmol, 2 eq.), 4,4′-dithiodibutyric acid (5.1 g, 21.3 mmol, 2.2 eq.) and DMAP (0.059 g, 0.49 mmol, 5 mol %) were added to a dry 250 mL round bottom flask followed by the addition of dichloromethane (153 mL) and a stir bar. The reaction was loosely covered and allowed to stir at room temperature for 24 h. A change in color and a cloudiness was observed within the first hour of the reaction indicating the formation of urea by-products. The reaction mixture was purified by filtration of urea solids and recrystallization from boiling toluene to obtain the disulfide of photoactive organic ligand IIIc.

Characterization of the disulfide of photoactive organic ligand IIIc: Melting point 239.3° C. ¹H NMR (500 MHZ, CDCl₃) δ_{H} (ppm) 7.68 (s, 2H), 6.98 (s, 2H), 5.47 (s, 2H), 3.95 (d, J=17.2 Hz, 6H), 2.71 (t, J=7.0 Hz, 2H), 2.54 (t, J=7.3 Hz, 2H), 2.05 (p, J=7.2 Hz, 2H). ¹³C NMR (125 MHz, CDCl₃) δ_{C} (ppm) 172.3, 153.5, 148.4, 140.1, 126.9, 110.7, 108.3, 63.4, 56.6, 56.5, 49.3, 37.6, 33.9, 32.5, 31.0, 25.7, 25.0, 24.1.

### Example 5—Preparation of Red-Emitting Nanoparticles Modified with Ligand IIIb and n-Decanethiol

A solution of InP/ZnSe/ZnS (NN-Labs® R16, 2 mL at 50 mg/mL in toluene) was precipitated using a mixture of acetonitrile and methanol (20 mL and 15 mL, respectively), and the resulting sample was centrifuged at 4200 rpm for 20 minutes to form a solid pellet, and the supernatant decanted. The solid pellet was taken up in 196 μL of chlorobenzene to a concentration of about 25 wt % and stirred for an hour to form a dispersion. A ligand solution of disulfide ligand IIIb (39.58 μL at 40 mg/mL in chloroform) and n-decanethiol (35.25 μL at 41.2 mg/mL in chlorobenzene) was prepared and the red InP/ZnSe/ZnS solution was added into the ligand solution and stirred at room temperature for 18 hours.

### Example 6—Preparation of Blue-Emitting Nanoparticles Modified with Ligand IIIb and n-Decanethiol

A solution of InP/ZnS (NN-Labs® B05, 2 mL at 50 mg/mL in toluene) was precipitated using a mixture of acetonitrile and methanol (20 mL and 15 mL, respectively), and the resulting sample was centrifuged at 4200 rpm for 20 minutes to form a solid pellet, and the supernatant decanted. The solid pellet was taken up in 196 μL of chlorobenzene to a concentration of about 25 wt % and stirred for an hour to form a dispersion. A ligand solution of disulfide ligand IIIb (39.58 μL at 40 mg/mL in chloroform) and n-decanethiol (35.25 μL at 41.2 mg/mL in chlorobenzene) was prepared and the blue InP/ZnS solution was added into the ligand solution and stirred at room temperature for 18 hours.

### Example 7—Photopatterning of Ink Containing Red-Emitting and Blue-Emitting Surface Modified Nanoparticles Along with Barium Titanate Particles

An ink formulation was prepared by combining the following: 1) 20 μl of the 25 wt % solution of Red Ink from Example 5; 2) 10 μl of 20 wt % BaTiO₃ (US Research Nanomaterials, Inc., 100 nm, cubic, suspended in toluene); 3) 20 μl of the 25 wt % solution of Blue Ink from Example 6. The ink formulation was blade coated onto a glass slide and dried to give a coating including: 41.9 wt % InP/ZnSe/ZnS red-emitting nanoparticles surface modified with ligand IIIb, 41.9 wt % of InP/ZnS blue-emitting nanoparticles surface modified with ligand IIIb, 16.3 wt % of BaTiO₃. The surface of the dried coating reflected light indicating by visual inspection relatively high-quality smoothness.

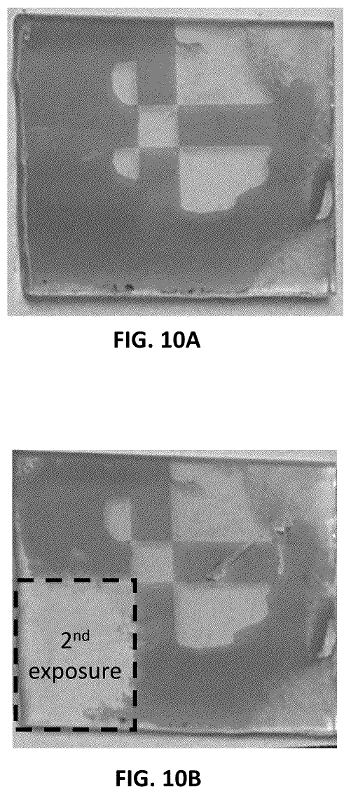

A sample square was positioned into a photolithography box equipped with a UV light source (365 nm) and a photomask was placed on top of the sample with the coated side up. UV light with a calculated dosage of approximately 25,000 mJ/cm² was applied. Development was carried out using a solution of Isopropyl Acetate. After about 1 minute of development with slight agitation, portions of the coating exposed to UV light were removed, while unexposed portions remained on the substrate. The patterned sample was removed from the developer and dried with compressed air. The dried patterned sample is shown in FIG. 10A.

A quarter portion of the patterned sample shown in FIG. 10A was covered with a second photomask, and the remaining portion was subjected to a second round of exposure with UV light at 365 nm at a calculated dosage of approximately 25,000 mJ/cm². The sample was then developed and dried as described above. The dried multipatterned sample is shown in FIG. 10B; the area outlined and labeled “second exposure” identifies the lower portion which was subjected to a second round of exposure to UV light. This demonstrates patterning using a single exposure development cycle versus two exposure development cycles.

### Example 8—Effect of Ligand Percentage on Conversion Efficiency

Ink Formulations A-D were prepared by combining amounts of the following: 1) 50 wt % solution of Red Ink from Example 5; 2) 20 wt % solution of Blue Ink from Example 6; 3) 20 wt % BaTiO₃ suspended in toluene; and 4) a mixture of butylamine, zinc chloride and hexanoic acid. Ink Formulations A-D were blade coated onto glass slides and dried to give Films A-D, respectively. The amount of ligand IIIb by weight with respect to weight of the nanoparticle was approximately 1×, 2×, 3×, and 10× for Films A, B, C and D, respectively. Compositions of Films A-D are summarized in Table 1.

TABLE 1

| | |
|---|---|
| Film Composition | Film |

| (wt %) | A | B | C | D |
|---|---|---|---|---|
| Approximate Relative | 1x | 2x | 3x | 10x |
| Amount of Ligand IIIb | | | | |
| Red Ink | 75.40 | 75.17 | 74.99 | 73.62 |
| Red NP/Ligand IIIb | | | | |
| Blue Ink | 15.08 | 15.03 | 15.00 | 14.72 |
| Blue NP/Ligand IIIb | | | | |
| Ligand IIIb | 0.24 | 0.54 | 0.78 | 2.59 |
| BaTiO₃ | 6.50 | 6.48 | 6.47 | 6.35 |
| Butylamine | 0.98 | 0.98 | 0.98 | 0.96 |
| ZnCl₂ | 0.22 | 0.22 | 0.22 | 0.22 |
| Hexanoic Acid | 1.57 | 1.56 | 1.56 | 1.53 |

Films A-D were photopatterned using UV LED light source (365 nm) with exposure 25,000 mJ/cm² for 120 sec. The exposed samples were developed using a solution mixture of MIBK (2 mL) and PC (0.5 mL). For each of Films A-D, the development occurred immediately after exposure to the developer solution (within 120 seconds of solvent exposure). Patterning quality was determined for a cross-shaped pattern with features having a width of 500 microns. For each of Films A-D, little or no deviation in the desired shape as compared to the shape of the photomask was observed. Optical densities of Films A-D were measured and ranged from 0.30 to 0.36. PLQY was approximately the same for all of the films.

### Example 9—Effect of Ligand Amount on Exposure Dosage

Films A and D were photopatterned as described for Example 8, for two different exposure times of 60 sec and 120 sec. Results are shown in Table 2. Pattern quality was visually inspected. If the “cross” pattern was fully intact with all of the exposed areas removed, this was considered “high” quality patterning. Any removal of the “cross” pattern or residue would downgrade the quality to “low”.

TABLE 2

| | Film | | | |
|---|---|---|---|---|
| | A | A | D | D |
| Time, | 60 sec, | 120 sec, | 60 sec, | 120 sec, |
| Exposure | 12,500 | 25,000 | 12,500 | 25,000 |
| | mJ/cm² | mJ/cm² | mJ/cm² | mJ/cm² |
| Development | Film did | Immediate | Immediate | Immediate |
| | not develop | | | |
| Patterning | Poor | High | High | High |
| Quality | | | | |

Reflectance Mode

| | | | | |
|---|---|---|---|---|
| PLQY (%) | 37.77 ± 0.15 | 37.77 ± 0.15 | 33.63 ± 0.25 | 33.63 ± 0.15 |
| Absorbance | 61.60 ± 0.21 | 61.60 ± 0.21 | 63.27 ± 2.16 | 63.27 ± 2.16 |
| (%) | | | | |

Transmission Mode

| | | | | |
|---|---|---|---|---|
| EQE | 13.90 ± 0.20 | 13.90 ± 0.20 | 13.67 ± 0.06 | 13.67 ± 0.06 |
| Absorbance | 56.83 ± 0.21 | 56.83 ± 0.21 | 56.50 ± 0.60 | 56.50 ± 0.60 |
| OD | 0.36 | 0.36 | 0.36 | 0.36 |

The presence of a higher ligand loading on the particles allowed for decreasing the dosage for effective patterning. Samples formed from Film D successfully developed at the lower UV dose, while the samples formed from Film A did not develop well at the lower UV dose. This suggests that higher saturation of ligands may be necessary if patterning thicker films at lower dosages is desired.

### Example 10—Effect of BaTiO₃ on Conversion Efficiency and Optical Density

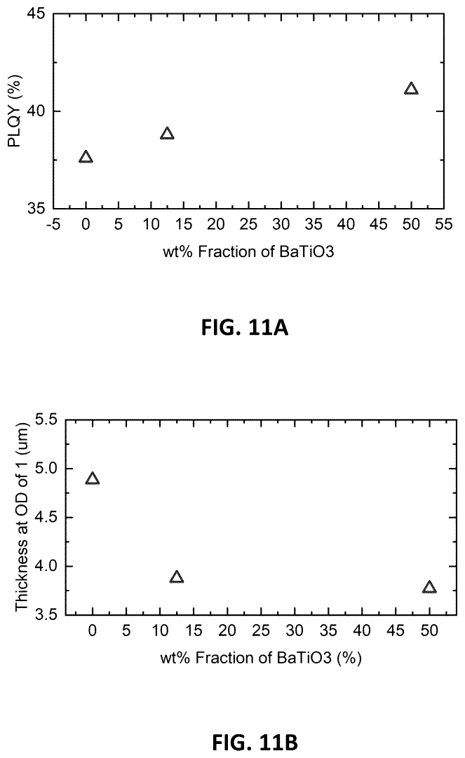

Ink formulations comprising InP based red-emitting nanoparticles were prepared with varying amounts of BaTiO₃. Corresponding Films E-G were prepared by mixing the nanoparticles together and blade coating. Absorbance and emission in reflectance mode were measured for each film. PLQY (%) values were calculated according to Eqn. 4 and plotted as a function of BaTiO₃ expressed as a fraction of weight percent. The film thickness of each sample was characterized by scratching the film and measuring the thickness difference using a profilometer. For each of Films E-G, thickness needed to reach an optical density of 1 as determined from Transmission mode data and plotted as a function of BaTiO₃ expressed as a fraction of weight percent. Results are shown in Table 3, and plots are shown in FIGS. 11A and 11B.

TABLE 3

| | Red NP | BaTiO3 | Absorbance | PLQY | Optical | Thickness |
|---|---|---|---|---|---|---|
| Film | % by wt | % by wt | (%) | (%) | Density | (μm) |
| E | 100 | 0 | 79.4 | 9 | 0.69 | 6.01 |
| F | 87.5 | 12.5 | 83.9 | 11.2 | 0.85 | 2.99 |
| G | 50 | 50 | 86.2 | 19.2 | 1.12 | 1.78 |

The data shown in FIG. 11A show that PLQY increases with addition of BaTiO₃ by a factor of 2 as a fraction of weight percent. The data shown in FIG. 11B show that the thickness needed to reach an optical density of 1 can be reduced by a factor of 3 compared to a film with no scattering particles. This suggests that the addition of BaTiO₃ and other scattering agents can improve optical density by serving its primary purpose as a scattering agent but also in a densely packed film, it can also perform the role of a separation material reducing the energy transfer probability between nanoparticles.

### Example 11—Effect of High Packing Density and Scattering Agents on the Optical Density Compared to Quantum Dots in a Photo Resin

An ink formulation comprising InP based red emitting nanoparticles and BaTiO₃ was prepared and coated at varying blade coating thicknesses and speeds to form a range of film thicknesses. Absorbance for each film was determined from Transmission mode data and the optical density was determined from Eqn. 5. The film thicknesses of each of the resulting films H-K was characterized by scratching the film and measuring the thickness difference using a profilometer.

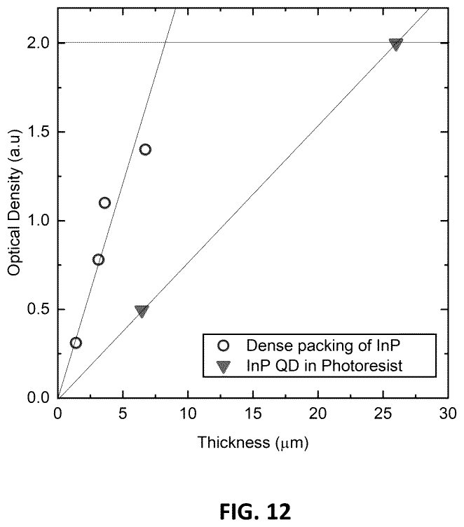

Photoresists including InP/ZnS based red emitting quantum dots have been investigated in Weng et al., “Fabrication and color conversion of patterned InP/ZnS quantum dots photoresist film via a laser-assisted route,” Optics & Laser Technology 140 (2021) 107026, incorporated herein by reference. To contrast the high packing density film, data for an InP/ZnS based film with 1.5 layers of Bragg Reflector pairs at a thickness of 6.47 μm as described by Weng et al. was used to calculate the optical density and plotted. The calculated optical densities and the corresponding thicknesses are shown in Table 4 and the plot is shown in FIG. 12.

TABLE 4

| | Calculated | Thickness |
|---|---|---|
| Film | Optical Density | (μm) |
| H | 0.31 | 1.39 |
| I | 0.78 | 3.13 |
| J | 1.1 | 3.62 |
| K | 1.4 | 6.74 |
| Reported¹ | 0.49 | 6.47 |

¹Weng et al.

### Further Inventive Concepts

1. A light responsive structural element comprising a patterned dense inorganic particle layer with an average thickness, excluding regions where the inorganic particle layer is absent, of at least about 5 average nanoparticle diameters and no more than about 15 microns comprising at least about 60 weight percent nanoparticles and no more than about 10 weight percent organic compositions, wherein the patterned dense particle layer comprises a first region with nanoparticles of a first type and optionally a second region with nanoparticles of a second type different from the first type by average particle size or chemical composition.

2. The light responsive structural element of further inventive concept 1 wherein the first region comprises at least about 60 wt. % of the surface modified nanoparticles.

3. The light responsive structural element of further inventive concept 1 wherein the first region comprises less than about 2 wt. % of polymeric binder.

4. The light responsive structural element of further inventive concept 1 wherein the first region does not comprise polymeric binder.

5. The light responsive structural element of further inventive concept 1 wherein the first region further comprises scattering particles having an average particle diameter of less than about 500 nm.

6. The light responsive structural element of further inventive concept 5 wherein a weight ratio of the scattering particles to the surface modified nanoparticles is from about 5:1 to about 1:20.

7. The light responsive structural element of further inventive concept 5 wherein the scattering particles have a lower refractive index compared to that of the surface modified nanoparticles.

8. The light responsive structural element of further inventive concept 5 wherein a refractive index of the scattering particles is different from that of the surface modified nanoparticles by at least about 0.25 index units.

9. The light responsive structural element of further inventive concept 5 wherein the scattering particles do not emit light.

10. The light responsive structural element of further inventive concept 5 wherein the scattering particles are selected from the group consisting of BaTiO₃, SiO₂, TiO₂, ZrO₂, diamond, HfO and mixtures thereof.

11. The light responsive structural element of further inventive concept 5 wherein the scattering particles are surface modified with ligands non-covalently bound to a surface of the scattering particles.

12. The light responsive structural element of further inventive concept 11 wherein the ligands comprise functional groups formed by photocleavage.

13. The light responsive structural element of further inventive concept 5 wherein the scattering particles are surface modified with ligands covalently bound to a surface of the scattering particles.

14. The light responsive structural element of further inventive concept 1 wherein the patterned dense inorganic particle layer is free of any organic matrix material.

15. The light responsive structural element of further inventive concept 1 wherein the patterned dense inorganic particle layer has a thickness of less than about 25 microns.

16. The light responsive structural element of further inventive concept 1 has an optical density for light at 450 nm of at least about 1 OD and a PLQY of at least about 50%. 17. The light responsive structural element of further inventive concept 1 having an optical density for light at 450 nm of at least about 0.7 OD and a PLQY of at least about 30%.

18. A light responsive structural element comprising a dense inorganic particle layer with an average thickness, excluding regions where the dense inorganic particle layer is absent, of at least about 5 average nanoparticle diameters and no more than about 15 microns comprising at least about 60 wt. % nanoparticles and no more than about 10 wt. % organic compositions, wherein the nanoparticles comprise no more than about 60 wt. % of a first nanoparticle type and at least about 40 wt. % of a second nanoparticle type having an energy bandgap larger than the first nanoparticle type by at least 0.2 eV.

19. The light responsive structural element of further inventive concept 18 wherein the second nanoparticle type has blue emission.

20. The light responsive structural element of further inventive concept 18 wherein the second nanoparticle type has an absorption band overlapping with an emission band of the first nanoparticle type.

21. The light responsive structural element of further inventive concept 18 wherein the dense inorganic particle layer further comprises scattering particles that do not exhibit luminescence.

22. The light responsive structural element of further inventive concept 21 wherein the scattering particles have an average particle diameter of less than about one micron.

23. The light responsive structural element of further inventive concept 21 wherein a weight ratio of the scattering particles to the first nanoparticle type is from about 5:1 to about 1:20.

24. The light responsive structural element of further inventive concept 21 wherein the scattering particles have a lower refractive index compared to that of the first nanoparticle type.

25. The light responsive structural element of further inventive concept 21 wherein a refractive index of the scattering particles is different from that of the first nanoparticle type by at least about 0.25 index units.

26. The light responsive structural element of further inventive concept 21 wherein the nanoparticles have an average smallest particle dimension of no more than about 20 nm and an average largest particle dimension of no more than 500 nm.

27. The light responsive structural element of further inventive concept 21 wherein the nanoparticles are surface modified with ligands bound to their surface.

28. The light responsive structural element of further inventive concept 27 wherein the ligands have functional groups formed from photocleavage.

29. The light responsive structural element of further inventive concept 18 having an optical density for light at 450 nm of at least about 1 OD and a PLQY of at least about 35%.

30. The light responsive structural element of further inventive concept 18 wherein the dense inorganic particle layer comprises a pattern on the substrate.

31. The light responsive structural element of further inventive concept 18 having an optical density for light at 450 nm of at least about 0.7 OD and a PLQY of at least about 30%.

32. The light responsive structural element of further inventive concept 18 wherein the second nanoparticle type comprises blue-emitting quantum confined luminescent nanoparticles and the first nanoparticle type comprises green-emitting quantum confined luminescent nanoparticles or red-emitting quantum confined light emitting nanoparticles.

33. The light responsive structural element of further inventive concept 18 wherein the first and/or second nanoparticle types comprise substantially spherical nanoparticles.

34. The light responsive structural element of further inventive concept 18 wherein the first and/or second nanoparticle types comprise non-spherical nanoparticles.

35. The light responsive structural element of further inventive concept 18 wherein the first and/or second nanoparticle types comprise CdSe or InP.

36. The light responsive structural element of further inventive concept 18 wherein the first and/or second nanoparticle types comprise nanoparticles having a core/shell composition of CdSe/CdS, CdSe/ZnS, CdSe/CdZnS, InP/ZnS, InP/ZnSe, or InP/ZnSe/ZnS.

37. The light responsive structural element of further inventive concept 18 wherein the first and/or second nanoparticle types comprise perovskite nanoparticles having the general formula ABX₃ wherein: A is monovalent cation of Cs, methylammonium, ethylammonium, formamidinium or a combination thereof; B is a cation of Bi, Cd, Mn, Pb, Sn or Zn or a combination thereof; and X is chloride, bromide or iodide.

38. The light responsive structural element of further inventive concept 18 wherein the layer is free of organic matrix polymer.

39. A light responsive structural element comprising a dense inorganic particle layer with an average thickness of at least about 5 average nanoparticle diameters and no more than about 25 microns comprising at least about 60 wt. % nanoparticles, no more than about 10 wt. % organic compositions and at least about 5 wt. % scattering particles with an average diameter of no more than a 500 nm.

40. The light responsive structural element of further inventive concept 39 wherein the scattering particles are not luminescent.

41. The light responsive structural element of further inventive concept 39 wherein the scattering particles have an average particle diameter of no more than about 300 nm.

42. The light responsive structural element of further inventive concept 39 wherein a weight ratio of the scattering particles to the nanoparticles is from about 5:1 to about 1:20.

43. The light responsive structural element of further inventive concept 39 wherein the scattering particles have a lower refractive index compared to that of the nanoparticles.

44. The light responsive structural element of further inventive concept 39 wherein a refractive index of the scattering particles is different from that of the nanoparticles by at least about 0.25 index units.

45. The light responsive structural element of further inventive concept 39 wherein the scattering particles are selected from the group consisting of BaTiO₃, SiO₂, TiO₂, ZrO₂, diamond, HfO and mixtures thereof.

46. The light responsive structural element of further inventive concept 39 wherein the scattering particles are surface modified with ligands.

47. The light responsive structural element of further inventive concept 39 wherein the scattering particles are surface modified with ligands having functional groups which may be altered by photocleavage.

48. The light responsive structural element of further inventive concept 39 wherein the dense inorganic particle mass comprises a pattern on the substrate.

49. The light responsive structural element of further inventive concept 39 having an optical density for light at 450 nm of at least about 0.7 OD and a PLQY of at least about 30%.

50. The light responsive structural element of further inventive concept 39 wherein the nanoparticles comprise quantum confined luminescent nanoparticles.

51. The light responsive structural element of further inventive concept 39 wherein the nanoparticles comprise substantially spherical nanoparticles.

52. The light responsive structural element of further inventive concept 39 wherein the nanoparticles comprise nonspherical nanoparticles.

53. The light responsive structural element of further inventive concept 39 wherein the nanoparticles comprise CdSe or InP.

54. The light responsive structural element of further inventive concept 39 wherein the nanoparticles have a core/shell composition of CdSe/CdS, CdSe/ZnS, CdSe/CdZnS, InP/ZnS, InP/ZnSe, or InP/ZnSe/ZnS.

55. The light responsive structural element of further inventive concept 39 wherein the nanoparticles comprise perovskite nanoparticles having the general formula ABX₃ wherein: A is monovalent cation of Cs, methylammonium, ethylammonium, formamidinium or a combination thereof; B is a cation of Bi, Cd, Mn, Pb, Sn or Zn or a combination thereof; and X is chloride, bromide or iodide.

56. The light responsive structural element of further inventive concept 39 wherein the layer is free of organic matrix polymer.

57. The light responsive structural element of further inventive concept 39 wherein the nanoparticles comprise a first nanoparticle type, and the dense inorganic particle layer further comprises nanoparticles of a second type having an energy bandgap smaller than the first nanoparticle type by at least about 0.2 eV.

58. The light responsive structural element of further inventive concept 57 wherein the first nanoparticle type has blue emission.

59. The light responsive structural element of further inventive concept 57 wherein the second nanoparticle type has an absorption band overlapping with an emission band of the first nanoparticle type.

60. The light responsive structural element of further inventive concept 57 wherein the first nanoparticle type comprises blue-emitting quantum confined luminescent nanoparticles and the second nanoparticle type comprises green-emitting quantum confined luminescent nanoparticles or red-emitting quantum confined luminescent nanoparticles.

61. A light responsive structural element comprising a dense inorganic particle layer with an average thickness of at least about 5 average nanoparticle diameters and no more than about 15 microns comprising at least about 60 wt. % nanoparticles, having an optical density for light at 450 nm of at least about 0.7 OD and a PLQY of at least about 30%.

62. The light responsive structural element of claim 61 wherein the dense inorganic particle layer has an optical density for light at 450 nm of at least about 1.5 OD.

63. The light responsive structural element of further inventive concept 61 wherein the nanoparticles comprise a first nanoparticle type and a second nanoparticle type.

64. The light responsive structural element of further inventive concept 63 wherein the energy bandgap of the second nanoparticle type is smaller than the first nanoparticle type by at least about 0.2 eV.

65. The light responsive structural element of further inventive concept 63 wherein the second nanoparticle type has an absorption band overlapping with an emission band of the first nanoparticle type.

66. The light responsive structural element of further inventive concept 63 wherein the first nanoparticle type comprises blue-emitting quantum confined luminescent nanoparticles and the second nanoparticle type comprises green-emitting quantum confined light emitting luminescent nanoparticles or red-emitting quantum confined luminescent nanoparticles.

67. The light responsive structural element of further inventive concept 63 wherein the first and/or second nanoparticle types comprise substantially spherical nanoparticles.

68. The light responsive structural element of further inventive concept 63 wherein the first and/or second nanoparticle types comprise nonspherical nanoparticles.

69. The light responsive structural element of further inventive concept 63 wherein the first and/or second nanoparticle types comprise CdSe or InP.

70. The light responsive structural element of further inventive concept 63 wherein the first and/or second nanoparticle types comprise nanoparticles having a core/shell composition of CdSe/CdS, CdSe/ZnS, CdSe/CdZnS, InP/ZnS, InP/ZnSe, or InP/ZnSe/ZnS.

71. The light responsive structural element of further inventive concept 63 wherein the first and/or second nanoparticle types comprise perovskite nanoparticles having the general formula ABX₃ wherein: A is monovalent cation of Cs, methylammonium, ethylammonium, formamidinium or a combination thereof; B is a cation of Bi, Cd, Mn, Pb, Sn or Zn or a combination thereof; and X is chloride, bromide or iodide.

72. The light responsive structural element of further inventive concept 61 wherein the dense inorganic particle layer further comprises scattering particles that are not luminescent.

73. The light responsive structural element of further inventive concept 72 wherein the scattering particles have an average particle diameter of less than about one micron.

74. The light responsive structural element of further inventive concept 72 wherein a weight ratio of the scattering particles to the nanoparticles is from about 5:1 to about 1:20.

75. The light responsive structural element of further inventive concept 72 wherein the scattering particles have a lower refractive index compared to that of the nanoparticles.

76. The light responsive structural element of further inventive concept 72 wherein a refractive index of the scattering particles is different from that of the nanoparticles by at least about 0.25 index units.

77. The light responsive structural element of further inventive concept 72 wherein the scattering particles are selected from the group consisting of BaTiO₃, SiO₂, TiO₂, ZrO₂, diamond, HfO and mixtures thereof.

78. The light responsive structural element of further inventive concept 72 wherein the scattering particles are surface modified with ligands.

79. The light responsive structural element of further inventive concept 72 wherein the scattering particles are surface modified with ligands having functional groups which may be altered by photocleavage.

80. The light responsive structural element of further inventive concept 61 wherein the dense inorganic particle layer is disposed on a substrate.

81. The light responsive structural element of further inventive concept 61 wherein the dense inorganic particle layer has a pattern on the substrate.

82. A method for radiation patterning a layer disposed on a substrate, the method comprising:
providing a layer comprising a collection of surface modified nanoparticles, wherein the surface modified nanoparticles comprise nanoparticles and photoactive organic ligands, each photoactive organic ligand comprising a linking group, a photoreactive group covalently bonded to the linking group, and the linking group binds the photoactive organic ligand to a surface of the nanoparticles, and the photoreactive group absorbs light to alter the solubility properties of the photoactive organic ligand;
irradiating the layer with radiation in an imagewise manner to form a first latent image comprising irradiated and non-irradiated portions of the layer, wherein irradiation results in the reaction of the photoreactive group in the irradiated portion; and
selectively removing portions of the irradiated or non-irradiated portions of the layer while the other portion remains substantially intact, to form a developed layer.

83. The method of further inventive concept 82 wherein the irradiated and non-irradiated portions have different solubilities in a polar solvent.

84. The method of further inventive concept 83 wherein the irradiated portions are more soluble in a polar solvent as compared to the non-irradiated portions.

85. The method of further inventive concept 83 wherein the polar solvent has a dielectric constant greater than 10.

86. The method of further inventive concept 83 wherein the polar solvent comprises at least one solvent selected from the group consisting of dimethylformamide, cyclopentanone, cyclohexanone, 2-butanone, methyl isobutyl ketone, methyl acetate, ethyl acetate, isopropyl acetate, hexyl acetate, propanol, propylene carbonate, octadecene, 4-methyl-2-pentanone and propylene glycol methyl ether acetate, or water.

87. The method of further inventive concept 82 wherein the cleavage results in the formation of an unbound organic compound.

88. The method of further inventive concept 82 wherein the activating group and the photoreactive group are the same group.

89. The method of further inventive concept 82 wherein the selective removal of the irradiated or non-irradiated portions of the layer does not fully remove the selectively removed portion, the method further comprising:
irradiating the developed layer with radiation in the same imagewise manner to form a second latent image comprising irradiated and non-irradiated portions of the developed layer, wherein irradiation result in the cleavage of at least a portion of the photocleavable group in the irradiated portion;
selectively removing portions of the irradiated or non-irradiated portions of the developed layer while the other portion remains substantially intact, to form a further developed layer.

90. The method of further inventive concept 82 wherein the irradiation is performed with ultraviolet light.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. A light responsive structural element comprising a dense inorganic particle layer with an average thickness of at least about 5 average nanoparticle diameters and no more than about 15 microns comprising at least about 60 wt. % nanoparticles, having an optical density for light at 450 nm of at least about 0.7 OD and a PLQY of at least about 30%.

2. The light responsive structural element of claim 1 wherein the dense inorganic particle layer has an optical density for light at 450 nm of at least about 1.5 OD.

3. The light responsive structural element of claim 1 wherein the nanoparticles comprise a first nanoparticle type and a second nanoparticle type.

4. The light responsive structural element of claim 3 wherein the energy bandgap of the second nanoparticle type is smaller than the first nanoparticle type by at least about 0.2 eV.

5. The light responsive structural element of claim 3 wherein the second nanoparticle type has an absorption band overlapping with an emission band of the first nanoparticle type.

6. The light responsive structural element of claim 3 wherein the first nanoparticle type comprises blue-emitting quantum confined luminescent nanoparticles and the second nanoparticle type comprises green-emitting quantum confined light emitting luminescent nanoparticles or red-emitting quantum confined luminescent nanoparticles.

7. The light responsive structural element of claim 3 wherein the first and/or second nanoparticle types comprise substantially spherical nanoparticles.

8. The light responsive structural element of claim 3 wherein the first and/or second nanoparticle types comprise nonspherical nanoparticles.

9. The light responsive structural element of claim 3 wherein the first and/or second nanoparticle types comprise CdSe or InP.

10. The light responsive structural element of claim 3 wherein the first and/or second nanoparticle types comprise nanoparticles having a core/shell composition of CdSe/CdS, CdSe/ZnS, CdSe/CdZnS, InP/ZnS, InP/ZnSe, or InP/ZnSe/ZnS.

11. The light responsive structural element of claim 3 wherein the first and/or second nanoparticle types comprise perovskite nanoparticles having the general formula ABX₃ wherein: A is monovalent cation of Cs, methylammonium, ethylammonium, formamidinium or a combination thereof; B is a cation of Bi, Cd, Mn, Pb, Sn or Zn or a combination thereof; and X is chloride, bromide or iodide.

12. The light responsive structural element of claim 1 wherein the dense inorganic particle layer further comprises scattering particles that are not luminescent.

13. The light responsive structural element of claim 12 wherein the scattering particles have an average particle diameter of less than about one micron.

14. The light responsive structural element of claim 12 wherein a weight ratio of the scattering particles to the nanoparticles is from about 5:1 to about 1:20.

15. The light responsive structural element of claim 12 wherein the scattering particles have a lower refractive index compared to that of the nanoparticles.

16. The light responsive structural element of claim 12 wherein a refractive index of the scattering particles is different from that of the nanoparticles by at least about 0.25 index units.

17. The light responsive structural element of claim 12 wherein the scattering particles are selected from the group consisting of BaTiO₃, SiO₂, TiO₂, ZrO₂, diamond, HfO and mixtures thereof.

18. The light responsive structural element of claim 12 wherein the scattering particles are surface modified with ligands.

19. The light responsive structural element of claim 12 wherein the scattering particles are surface modified with ligands having functional groups which may be altered by photocleavage.

20. The light responsive structural element of claim 1 wherein the dense inorganic particle layer is disposed on a substrate.

21. The light responsive structural element of claim 1 wherein the dense inorganic particle layer has a pattern on the substrate.

22. The light responsive structural element of claim 3 wherein the first nanoparticle type comprises green-emitting quantum confined luminescent nanoparticles and the second nanoparticle type comprises red-emitting quantum confined light emitting luminescent nanoparticles.
